(19) United States
(12) Patent Application Publication
(10) Pub. No.: US 2018/0002569 A1
(43) Pub. Date: Jan. 4, 2018

(54) CURABLE SILICONE FORMULATIONS AND RELATED CURED PRODUCTS, METHODS, ARTICLES, AND DEVICES

(71) Applicant: Dow Corning Corporation, Midland, MI (US)

(72) Inventors: Ranjith Samuel John, Midland, MI (US); Herman Meynen, Lubbeek (BE); Thomas Seldrum, Ath (BE); Craig R. Yeakle, Midland, MI (US)

(21) Appl. No.: 15/544,947

(22) PCT Filed: Jan. 22, 2016
(86) PCT No.: PCT/US2016/014417

§ 371 Date: Jul. 20, 2017

Related U.S. Application Data
(60) Provisional application No. 62/111,225, filed on Feb. 3, 2015.

(51) Int. Cl. C09D 183/06; B81B 3/00; H01L 21/683; H01L 23/00; H01L 23/29; H01L 21/56

(52) U.S. Cl. CPC C09D 183/06; H01L 23/296; H01L 21/563; H01L 21/6836; H01L 24/29; B81B 3/0078; B81B 2203/0127; H01L 2221/68381; H01L 2224/29191

(57) ABSTRACT

The invention comprises a butyl acetate-silicone formulation comprising (A) an organopolysiloxane containing an average of at least two silicon-bonded alkenyl groups per molecule, (B) an organosilicon compound containing an average of at least two silicon-bonded hydrogen atoms per molecule; (C) a hydrosilylation catalyst; and a coating effective amount of (D) butyl acetate. The invention also comprises related silicone formulations made by removing a portion, or all, of (D) butyl acetate therefrom, and related cured products, methods, articles and devices.

The present invention generally relates to silicone formulations containing butyl acetate, formulations prepared therefrom by removing the butyl acetate, and related cured products, methods, articles and devices.

U.S. Pat. No. 6,617,674 B2 to Becker et al. for Dow Corning Corporation describes a semiconductor package comprising a wafer having an active surface comprising at least one integrated circuit, wherein each integrated circuit has a plurality of bond pads; and a cured silicone layer covering the surface of the wafer, provided at least a portion of each bond pad is not covered with the cured silicone layer and wherein the cured silicone layer is prepared by the method thereof.

U.S. Pat. No. 8,072,689 B2; U.S. Pat. No. 8,363,330 B2; and U.S. Pat. No. 8,542,445 B2, all to Bolis or Bolis et al., mention optical devices with deformable membranes.

U.S. Pat. No. 8,440,312 B2 to Elahee for Dow Corning Corporation describes a curable composition that contains (A) a polyorganosiloxane base polymer having an average per molecule of at least two aliphatically unsaturated organic groups, optionally (B) a crosslinker having an average per molecule of at least two silicon bonded hydrogen atoms, (C) a catalyst, (D) a thermally conductive filler, and (E) an organic plasticizer. The composition can cure to form a thermally conductive silicone gel or rubber. The thermally conductive silicone rubber is useful as a thermal interface material, in both TIM1 and TIM2 applications. The curable composition may be wet dispensed (e.g., dispensed as is) and then cured in situ in an (opto)electronic device, or the curable composition may be first cured to form a pad with or without a support before installation in an (opto)electronic device (i.e., pad formed, then installed).

We (the present inventors) have discovered or recognized problems with certain silicone formulations containing a solvent, and concentrated silicone formulations and cured silicone products made therefrom by removing the solvent. Some problems are solvent-caused, wherein the solvent has a boiling point (b.p.) that is either too low or too high; others are impurity caused; and others are of unknown cause. We found such problems with hydrosilylation curable silicone formulations comprising an alkenyl-functional organopolysiloxane, a SiH-functional organosilicon compound, a hydrosilylation catalyst, and a solvent and with concentrated silicone formulations made therefrom by removing the solvent, e.g., in a so-called soft bake step. It the boiling point of the solvent is too low, it may be difficult to prevent premature drying and non-uniformity of films made from the formulation. If the boiling point of the solvent is too high, it may be difficult to remove the solvent from the films without causing premature curing (e.g., gelation) thereof. Whether caused by a solvent with a boiling point that we found is too low (e.g., ethyl acetate b.p. 76.5 to 77.5 degrees Celsius (° C.) or toluene b.p. 110°-111° C.) or by a solvent with a boiling point that we found is too high (e.g., xylenes b.p. 137°-140° C., mesitylene b.p. 163°-166° C., and gamma-butyrolactone b.p. 204°-205° C.), the volatility/non-volatility characteristics of the solvent may render the resulting films unusable due to solvent-driven defects. Also, edge bead removal may be difficult to do when the film contains a higher boiling aromatic hydrocarbon solvent such as mesitylene, as the film may continue spreading out even at spin speeds less than 1,000 rpm. Thus, when the solvent is mesitylene, a soft bake step may be needed to remove the mesitylene before doing edge bead removal step. Even if the mesitylene is soft baked out, however, if the thickness of the resulting soft baked film is a few micrometers, such a thin film may contain defects. Separately, we found the choice of solvent may negatively affect the dielectric strength of the film, where a poor solvent may produce a film having insufficient dielectric strength for use as a passivation layer.

We have also discovered the silicone formulations may have a too-short shelf life or a cyclic siloxanes content that is higher than that desired for environmental, health or safety (EH&S) reasons. Also, after soft baking a film of the formulation, the resulting concentrated silicone formulation (substantially free of the aromatic hydrocarbon solvent) may have insufficient adhesiveness to certain materials such as Si, SiC, or SiN, rendering the film difficult to use therewith.

After research and testing we happily report our inventive solution to one or more of these problems. Our inventive solution may improve any silicone formulation and concentrated silicone formulation made therefrom suffering from such problem(s) and in need of our solution, including, but not limited to, those of U.S. Pat. No. 6,617,674 B2 to Becker G. S. et al., for Dow Corning Corporation.

### SUMMARY OF THE INVENTION

The present invention provides silicone formulations containing butyl acetate, formulations prepared therefrom by removing the butyl acetate, and related cured products, methods, articles and devices.

The inventive methods, formulations, products, articles, devices and packages are useful in numerous end uses and applications, especially, for example, for forming and comprising an optical membrane and for forming and comprising a photopatterned film; with the proviso that each one of the inventive embodiments lacks (i.e., is free of) a thermally conductive filler. The invention article produced via the invention method is suitable for use in numerous end uses and applications.

### BRIEF DESCRIPTION OF THE DRAWINGS

Other advantages and aspects of this invention may be described in the following detailed description when considered in connection with the accompanying drawings wherein:

FIG. 1 is a flowchart showing a coating and photopatterning process for use with the respective butyl acetate-silicone formulation and concentrated silicone formulation.

FIG. 2 is a graph plotting stress versus temperature for thermal cycling Trial 1 (diamonds), Trial 2 (squares), and Trial 3 (triangles).

FIG. 3 is a cross-section view of a scanning electron microscopy (SEM) image of a line space in an example of an inventive photopatterned film/wafer laminate.

FIG. 4 is a graph of a spin curve plotting film thickness versus weight percent solids concentration at 2,000 revolutions per minute (rpm).

FIG. 5 is a photograph of a photopatterned cured silicone film/wafer laminate of Example 7A with imperfectly formed vias in the film.

FIGS. 6 to 12 are photographs of photopatterned cured silicone film/wafer laminates of Examples 7B to 7H, respectively, with completely formed vias in the films.

### DETAILED DESCRIPTION OF THE INVENTION

The Brief Summary and the Abstract are hereby incorporated by reference. In some embodiments there are any one of the following numbered aspects.

Aspect 1. A butyl acetate-silicone formulation comprising (A) an organopolysiloxane containing an average, per molecule, of at least two silicon-bonded alkenyl groups; (B) an organosilicon compound containing an average of at least two silicon-bonded hydrogen atoms per molecule; (C) a hydrosilylation catalyst; and a coating effective amount of (D) butyl acetate; with the proviso that the formulation lacks (is free of) each of the following constituents: a thermally conductive filler; an organopolysiloxane having, on average, at least two silicon-bonded aryl groups and at least two silicon-bonded hydrogen atoms in the same molecule; a phenol; a fluoro-substituted acrylate; iron; and aluminum.

Aspect 2. A concentrated silicone formulation made by removing most, but not all, butyl acetate from the butyl acetate-silicone formulation of aspect 1 without curing same, the formulation consisting essentially of (A) an organopolysiloxane containing an average, per molecule, of at least two alkenyl groups; (B) an organosilicon compound containing an average, per molecule, of at least two silicon-bonded hydrogen atoms in a concentration sufficient to cure the formulation; a catalytic amount of (C) a hydrosilylation catalyst; and a residual amount of (D) butyl acetate; with the proviso that the formulation lacks (is free of) each of the following constituents: a thermally conductive filler; an organopolysiloxane having, on average, at least two silicon-bonded aryl groups and at least two silicon-bonded hydrogen atoms in the same molecule; a phenol; a fluoro-substituted acrylate; iron; and aluminum.

Aspect 3. The formulation of aspect 1 or 2 wherein (C) the hydrosilylation catalyst is a photoactivatable hydrosilylation catalyst.

Aspect 4. A method of making a concentrated silicone formulation from a butyl acetate-silicone formulation comprising (A) an organopolysiloxane containing an average, per molecule, of at least two silicon-bonded alkenyl groups; (B) an organosilicon compound containing an average of at least two silicon-bonded hydrogen atoms per molecule; (C) a hydrosilylation catalyst; and a coating effective amount of (D) butyl acetate; with the proviso that the butyl acetate-silicone formulation lacks (is free of) a thermally conductive filler, the method comprising coating and/or soft baking the butyl acetate-silicone formulation so as to remove from 90 percent to less than 100 percent of the coating effective amount of (D) butyl acetate therefrom without curing same so as to give a concentrated silicone formulation consisting essentially of (A) an organopolysiloxane containing an average, per molecule, of at least two alkenyl groups; (B) an organosilicon compound containing an average, per molecule, of at least two silicon-bonded hydrogen atoms; a catalytic amount of (C) a hydrosilylation catalyst; and a residual amount of (D) butyl acetate; with the proviso that the formulation lacks (is free of) a thermally conductive filler.

Aspect 5. A method of making a butyl acetate free curable silicone formulation, the method comprising removing all of the (D) butyl acetate from a butyl acetate-silicone formulation or a concentrated silicone formulation without curing same to give a butyl acetate-free silicone formulation consisting essentially of (A) an organopolysiloxane containing an average, per molecule, of at least two alkenyl groups; (B) an organosilicon compound containing an average, per molecule, of at least two silicon-bonded hydrogen atoms; a catalytic amount of (C) a hydrosilylation catalyst; and lacking (being free of) butyl acetate; with the proviso that the formulation lacks (is free of) a thermally conductive filler; wherein prior to the removing step the butyl acetate silicone formulation comprised (A) an organopolysiloxane containing an average, per molecule, of at least two silicon-bonded alkenyl groups; (B) an organosilicon compound containing an average of at least two silicon-bonded hydrogen atoms per molecule; (C) a hydrosilylation catalyst; and a coating effective amount of (D) butyl acetate; with the proviso that the butyl acetate-silicone formulation lacks (is free of) a thermally conductive filler; and wherein prior to the removing step the concentrated silicone formulation consisted essentially of (A) an organopolysiloxane containing an average, per molecule, of at least two alkenyl groups; (B) an organosilicon compound containing an average, per molecule, of at least two silicon-bonded hydrogen atoms in a concentration sufficient to cure the formulation; a catalytic amount of (C) a hydrosilylation catalyst; and a residual amount of (D) butyl acetate; with the proviso that the concentrated silicone formulation lacks (is free of) a thermally conductive filler.

Aspect 6. A method of making a cured silicone product, the method comprising removing all of the (D) butyl acetate from a butyl acetate-silicone formulation or a concentrated silicone formulation without curing same to give a butyl acetate-free curable silicone formulation and hydrosilylation curing the butyl acetate-free curable silicone formulation to give the cured silicone product; with the proviso that the product lacks (is free of) a thermally conductive filler; wherein prior to the removing step the butyl acetate silicone formulation comprised (A) an organopolysiloxane containing an average, per molecule, of at least two silicon-bonded alkenyl groups; (B) an organosilicon compound containing an average of at least two silicon-bonded hydrogen atoms per molecule; (C) a hydrosilylation catalyst; and a coating effective amount of (D) butyl acetate; with the proviso that the butyl acetate-silicone formulation lacks (is free of) a thermally conductive filler; and wherein prior to the removing step the concentrated silicone formulation consisted essentially of (A) an organopolysiloxane containing an average, per molecule, of at least two alkenyl groups; (B) an organosilicon compound containing an average, per molecule, of at least two silicon-bonded hydrogen atoms in a concentration sufficient to cure the formulation; a catalytic amount of (C) a hydrosilylation catalyst; and a residual amount of (D) butyl acetate; with the proviso that the concentrated silicone formulation lacks (is free of) a thermally conductive filler.

Aspect 7. A method of forming a temporary-bonded substrate system comprising sequentially a functional substrate, a release layer, an adhesive layer, and a carrier substrate; the method comprising steps (a) to (d): (a) applying a butyl acetate-silicone formulation or a concentrated silicone formulation to a surface of the carrier substrate to form a film of the formulation on the carrier substrate; (b) soft baking the film of step (a) so as to remove butyl acetate therefrom without curing the film to give a butyl acetate-free curable film/carrier substrate article; (c) in a bond chamber under vacuum, contacting the butyl acetate-free curable film of the article of step (b) to the release layer of a functional substrate/release layer article to give a contacted substrate system comprising sequentially a functional substrate, a release layer, a butyl acetate-free curable film, and a carrier substrate; and (d) in the bond chamber under vacuum exposing the contacted substrate system to an applied force of from greater than 1,000 Newtons (N) to 10,000 N and a temperature from 125 degrees Celsius (° C.) to 300° C. so as to partially cure the butyl acetate-free curable film to give a partially cured film in the contacted substrate system; and heating the contacted substrate system with the partially cured film at ambient pressure to give a temporary-bonded substrate system comprising sequentially the functional substrate, the release layer, an adhesive layer, and the carrier substrate; wherein prior to the (a) applying step the butyl acetate silicone formulation comprised (A) an organopolysiloxane containing an average, per molecule, of at least two silicon-bonded alkenyl groups; (B) an organosilicon compound containing an average of at least two silicon-bonded hydrogen atoms per molecule; (C) a hydrosilylation catalyst; and a coating effective amount of (D) butyl acetate; with the proviso that the butyl acetate-silicone formulation lacks (is free of) a thermally conductive filler; and wherein prior to the (a) applying step the concentrated silicone formulation consisted essentially of (A) an organopolysiloxane containing an average, per molecule, of at least two alkenyl groups; (B) an organosilicon compound containing an average, per molecule, of at least two silicon-bonded hydrogen atoms in a concentration sufficient to cure the formulation; a catalytic amount of (C) a hydrosilylation catalyst; and a residual amount of (D) butyl acetate; with the proviso that the concentrated silicone formulation lacks (is free of) a thermally conductive filler.

Aspect 8. The method of aspect 7 wherein step (a) further comprises exposing the film of the formulation on the carrier substrate article to ultraviolet radiation having a wavelength comprising I-line radiation so as to produce an exposed film on the carrier substrate.

Aspect 9. The method of aspect 7 or 8 further comprising a step of forming the functional substrate/release layer article prior to step (c) by soft baking a film of a solvent-containing release layer composition on the functional substrate so as to remove the solvent therefrom to give the functional substrate/release layer article.

Aspect 10. The method of aspect 7, 8, or 9 wherein the functional substrate is a device wafer; steps (c) and (d) are performed simultaneously; or both the functional substrate is a device wafer and steps (c) and (d) are performed simultaneously. Alternatively, the method of aspect 7 wherein: step (a) further comprises exposing the film of the formulation on the carrier substrate article to ultraviolet radiation having a wavelength comprising I-line radiation so as to produce an exposed film on the carrier substrate; or the method further comprises a step of forming the functional substrate/release layer article prior to step (c) by soft baking a film of a solvent-containing release layer composition on the functional substrate so as to remove the solvent therefrom to give the functional substrate/release layer article; or step (a) further comprises exposing the film of the formulation on the carrier substrate article to ultraviolet radiation having a wavelength comprising I-line radiation so as to produce an exposed film on the carrier substrate and the method further comprises a step of forming the functional substrate/release layer article prior to step (c) by soft baking a film of a solvent-containing release layer composition on the functional substrate so as to remove the solvent therefrom to give the functional substrate/release layer article; or the functional substrate is a device wafer; or steps (c) and (d) are performed simultaneously; or both the functional substrate is a device wafer and steps (c) and (d) are performed simultaneously.

Aspect 11. The temporary-bonded substrate system made by the method of any one of aspects 7 to 10.

Aspect 12. A method of debonding, the method comprising subjecting the temporary-bonded substrate system of aspect 11 to a debonding condition comprising applying a mechanical force so as to separate the functional substrate from the carrier substrate or vice versa to give an intact functional substrate.

Aspect 13. A method of forming a permanent-bonded substrate system sequentially consisting essentially of a functional substrate/adhesive layer/carrier substrate, the method comprising steps (a) to (d): (a) applying a butyl acetate-silicone formulation or a concentrated silicone formulation to a surface of the carrier substrate or the functional substrate to form an article of a film of the formulation on the carrier substrate or the functional substrate; (b) soft baking the film of the article of step (a) so as to remove butyl acetate therefrom without curing the film to give an article of a butyl acetate-free curable film on the carrier substrate or the functional substrate; (c) in a bond chamber under vacuum, contacting the butyl acetate-free curable film of step (b) to the other of the carrier substrate or functional substrate to give a contacted substrate system consisting essentially of sequentially a functional substrate, a butyl acetate-free curable film, and a carrier substrate; and (d) in the bond chamber under vacuum exposing the contacted substrate system to an applied force of from greater than 1,000 Newtons (N) to 10,000 N and a temperature from 125 degrees Celsius (° C.) to 300° C. so as to partially cure the butyl acetate-free curable film to give a partially cured film in the contacted substrate system; and heating the contacted substrate system with the partially cured film at ambient pressure to give a permanent-bonded substrate system consisting essentially of sequentially the functional substrate, an adhesive layer, and the carrier substrate; wherein prior to the (a) applying step the butyl acetate silicone formulation comprised (A) an organopolysiloxane containing an average, per molecule, of at least two silicon-bonded alkenyl groups; (B) an organosilicon compound containing an average of at least two silicon-bonded hydrogen atoms per molecule; (C) a hydrosilylation catalyst; and a coating effective amount of (D) butyl acetate; with the proviso that the butyl acetate-silicone formulation lacks (is free of) a thermally conductive filler; and wherein prior to the (a) applying step the concentrated silicone formulation consisted essentially of (A) an organopolysiloxane containing an average, per molecule, of at least two alkenyl groups; (B) an organosilicon compound containing an average, per molecule, of at least two silicon-bonded hydrogen atoms in a concentration sufficient to cure the formulation; a catalytic amount of (C) a hydrosilylation catalyst; and a residual amount of (D) butyl acetate; with the proviso that the concentrated silicone formulation lacks (is free of) a thermally conductive filler.

Aspect 14. An article comprising a substrate and a butyl acetate-silicone formulation or a concentrated silicone formulation, wherein the formulation is disposed on the substrate; wherein the butyl acetate silicone formulation comprises (A) an organopolysiloxane containing an average, per molecule, of at least two silicon-bonded alkenyl groups; (B) an organosilicon compound containing an average of at least two silicon-bonded hydrogen atoms per molecule; (C) a hydrosilylation catalyst; and a coating effective amount of (D) butyl acetate; with the proviso that the butyl acetate-silicone formulation lacks (is free of) a thermally conductive filler; and wherein the concentrated silicone formulation consists essentially of (A) an organopolysiloxane containing an average, per molecule, of at least two alkenyl groups; (B) an organosilicon compound containing an average, per molecule, of at least two silicon-bonded hydrogen atoms in a concentration sufficient to cure the formulation; a catalytic amount of (C) a hydrosilylation catalyst; and a residual amount of (D) butyl acetate; with the proviso that the concentrated silicone formulation lacks (is free of) a thermally conductive filler.

Aspect 15. An optical article comprising an element for transmitting light, the element comprising the cured silicone product made by the method of aspect 6. Alternatively, an element for transmitting light for use in an optical article or optical device, wherein the element for transmitting light is the cured silicone product made by the method of claim 6.

Aspect 16. The optical article of aspect 15 wherein the cured silicone product is an optical protective layer or a deformable membrane for use in a microelectromechanical system (MEMS).

Aspect 17. A deformable membrane for use in an optical device configured therefor, wherein the deformable membrane is the cured silicone product made by the method of aspect 6.

Aspect 18. An optical device with a deformable membrane, the device comprising: (a) a deformable membrane having front and rear faces and a peripheral area which is anchored in a sealed manner on a support helping to contain a constant volume of liquid in contact with the rear face of the membrane, said peripheral area is an anchoring area that is a sole area of the membrane that is anchored on the support; and a substantially central area, configured to be deformed reversibly from a rest position; and (b) an actuation device configured for displacing the liquid in the central area, stressing the membrane in at least one area situated strictly between the central area and the anchoring area, wherein the deformable membrane is the cured silicone product made by the method of aspect 6.

Aspect 19. A method of preparing a cured silicone layer of a semiconductor package comprising a semiconductor device wafer having an active surface comprising a plurality of surface structures including bond pads, scribe lines, and other structures; and a cured silicone layer covering the active surface of the wafer except the bond pads and scribe lines, the method comprising the steps of: (i) applying a butyl acetate-silicone formulation to the active surface of the semiconductor device wafer to form a coating thereon, wherein the active surface comprises a plurality of surface structures; (ii) removing from 90 percent to less than 100 percent of the coating effective amount of (D) butyl acetate from the coating so as to give a film of a formulation consisting essentially of (A) an organopolysiloxane containing an average, per molecule, of at least two alkenyl groups; (B) an organosilicon compound containing an average, per molecule, of at least two silicon-bonded hydrogen atoms in a concentration sufficient to cure the formulation; a catalytic amount of (C) a hydrosilylation catalyst; and a residual amount of (D) butyl acetate; (iii) exposing a portion of the film to radiation having a wavelength comprising I-line radiation without exposing another portion of the film to the radiation so as to produce a partially exposed film having non-exposed regions covering at least a portion of each bond pad and exposed regions covering the remainder of the active surface; (iv) heating the partially exposed film for an amount of time such that the exposed regions are substantially insoluble in a developing solvent and the non-exposed regions are soluble in the developing solvent; (v) removing the non-exposed regions of the heated film with the developing solvent to form a patterned film; and (vi) heating the patterned film for an amount of time sufficient to form the cured silicone layer; wherein prior to the (a) applying step the butyl acetate silicone formulation comprised (A) an organopolysiloxane containing an average, per molecule, of at least two silicon-bonded alkenyl groups; (B) an organosilicon compound containing an average of at least two silicon-bonded hydrogen atoms per molecule; (C) a hydrosilylation catalyst; and a coating effective amount of (D) butyl acetate; with the proviso that the butyl acetate-silicone formulation lacks (is free of) a thermally conductive filler.

Aspect 20. The method of aspect 19, wherein constituents (A) and (B) are proportioned in the butyl acetate-silicone formulation in such a way so as to configure the formulation with a SiH-to-alkenyl ratio, and the SiH-to-alkenyl ratio is from 0.65 to 1.05.

Aspect 21. The method of aspect 19 or 20, wherein the developing solvent is butyl acetate. Alternatively, the method of aspect 19 wherein constituents (A) and (B) are proportioned in the butyl acetate-silicone formulation in such a way so as to configure the formulation with a SiH-to-alkenyl ratio, and the SiH-to-alkenyl ratio is from 0.65 to 1.05; or the developing solvent is butyl acetate; or constituents (A) and (B) are proportioned in the butyl acetate-silicone formulation in such a way so as to configure the formulation with a SiH-to-alkenyl ratio, and the SiH-to-alkenyl ratio is from 0.65 to 1.05 and the developing solvent is butyl acetate.

Aspect 22. A cured silicone layer formed by the method of aspect 19, 20 or 21.

Aspect 23. A semiconductor package comprising a semiconductor device wafer having an active surface comprising a plurality of surface structures including bond pads, scribe lines, and other structures; and a cured silicone layer covering the active surface of the wafer except the bond pads and scribe lines, wherein the cured silicone layer is prepared by the method of any one of aspects 19-21.

Aspect 24. An electronic article comprising a dielectric layer disposed on a silicon nitride layer, the dielectric layer being made of the cured silicone product made by the method of aspect 6 and, when the dielectric layer is up to 40 micrometers thick, the dielectric layer is characterized by a dielectric strength greater than 1.5×10⁶ Volts per centimeter (V/cm).

Aspect 25. The invention of any one of aspects 4-24, wherein each formulation also lacks (is free of) each of the following constituents: an organopolysiloxane having, on average, at least two silicon-bonded aryl groups and at least two silicon-bonded hydrogen atoms in the same molecule; a phenol; a fluoro-substituted acrylate; iron; and aluminum.

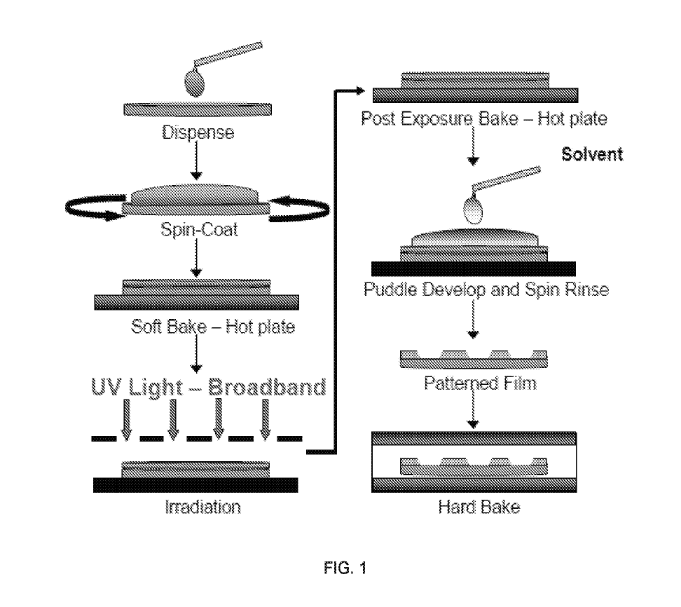

Some embodiments and aspects are illustrated in FIGS. 1 to 12.

FIG. 1 is a flowchart showing a coating and photopatterning process for use with the respective butyl acetate-silicone formulation and concentrated silicone formulation. The process is exemplary of the inventive methods of forming a 40 micrometer (μm) thick “wet” film of the butyl acetate-silicone formulation, making a 40 μm thick photopatternable film of the concentrated silicone formulation therefrom, and photopatterning the film of the formulation.

Following the direction of the arrows in FIG. 1, in the “Dispense” step a quantity of a sample sufficient for forming the “wet” film of the butyl acetate-silicone formulation is dispensed on a substrate such as a device wafer (e.g., a semiconductor device wafer, e.g., a gallium arsenide wafer, a silicon (Si) wafer, a silicon carbide (SiC) wafer, a Si wafer having a SiO_{X} layer disposed thereon, or a Si wafer having a SiN layer disposed thereon) to give a “wet” film/wafer. Subscript x is a rational or irrational number expressing the average number of oxygen atoms per one silicon atom in a silicon oxide layer. Typically, x is from 1 to 4.

Next in FIG. 1, in the “Spin-Coat” step, the “wet” film/wafer is rotated at a maximum spin speed of 1,000 rpm for about 20 seconds to form a 40 micrometer (μm) thick film of the butyl acetate-silicone formulation on the wafer. Alternatively, the spinning may remove a majority amount of the butyl acetate from the film to give a film of the concentrated silicone formulation on the wafer. The higher the spin speed, the lower the amount of butyl acetate remaining in the spun-on film. If desired, the amount of butyl acetate remaining in the film may be readily determined using Fourier Transform Infrared (FT-IR) spectroscopy. Either film may be directly subjected to an edge bead removal step. Alternatively the film may be subjected to an optional soft bake step as described below.

Next in FIG. 1, in the “Soft Bake Hot plate” step, and the resulting sample film/wafer laminate is placed on a hot plate, and gently heated (“soft baked”) at 110 degrees Celsius (° C.) for 1 to 2 minutes to remove the residual amount of butyl acetate from the film, and removed from the hot plate to give a film of the butyl acetate-free curable silicone formulation/wafer laminate. If the film has not been directly subjected to the edge bead removal step as part of the spin-coat step above, then the film may be subjected to this soft bake step followed by an edge bead removal step.

Next in FIG. 1, in the “Irradiation” step, a photomask defining an array of spaced-apart, square-shaped mask portions having 40 μm sides (“islands” or lines) and an open portion (unmasked portion) surrounding the mask portions (“sea”) is placed above, and spaced apart from, the film of the formulation of the film/wafer laminate to define 40 μm square unexposed areas on the film and a remaining unmasked or exposed area on the surface of the film, and the exposed portion (“sea”) of the film is dosed with a total of 1,000 millijoules per square centimeter (mJ/cm²) of broadband ultraviolet light or I-line (365 nm) UV light through the photomask (irradiating the exposed portion of the film for 50 seconds at 20 mJ/cm² per second). The unexposed portions (e.g., “islands” or lines) of the film are not dosed, to give a negative-type resist film/wafer laminate.

Next in FIG. 1, in the “Post Exposure Bake Hot plate” step, the negative-type resist film/wafer laminate is placed on a hot plate and heated at from 130° to 145° C. (e.g., 135° C.) for from 1 to 5 minutes (e.g., 2 minutes) to lightly crosslink the exposed portion (“sea”) of the resist film while leaving the unexposed portions (“islands”) uncrosslinked, and then the post-exposure baked laminate is removed from the hot plate to give a post-exposure baked film/wafer laminate. The temperature and time used in the post-exposure bake step may be varied to accommodate substrates of different materials, thicknesses, or optional additional layer(s) disposed between the negative-type resist film and the substrate. Examples of optional additional layers are metal underlayers and silicon nitride films deposited using PECVD (plasma-enhanced chemical vapor deposition) methods.

Next in FIG. 1, in the “Puddle Develop and Spin Rinse” step, a developer solvent, butyl acetate, is dispensed as a first puddle on the film of the post-exposure baked film/wafer laminate to dissolve the unexposed portions (“islands”) of the film, and then the resulting first puddle laminate is spin rinsed by first allowing the first puddle to sit (static) for 30 seconds, then spinning the first puddle laminate at from 170 to 1,000 rpm (e.g., from 200 to 300 rpm) to give a remaining film/wafer laminate. Then, not indicated in FIG. 1, dispense additional butyl acetate to form a second puddle on the remaining film of the remaining film/wafer laminate and give a second puddle laminate, allow the resulting second puddle laminate to sit (static) for 30 seconds, and then spinning the second puddle laminate at a maximum speed of up to 3,000 rpm (e.g., 1,500 rpm) to remove the additional butyl acetate to give a patterned film/wafer laminate. Typically, some of the exposed portion (“sea”) is also dissolved by the butyl acetate such that the height of the patterned film after this developing step may be from 80% to 90% of the height of the post-exposure baked film. The remaining height is referred to herein as film retention (%). Conversely, the height of the post-exposure baked film may be said to experience film loss (%) of 20% to 10%, respectively.

Next in FIG. 1, the patterned film/wafer laminate is placed in an oven and heated (“hard baked”) at, for example, 180° for 3 hours or at 200° C. for 2 hours or at 250° C. for 30 minutes to give an inventive article comprising a photopatterned cured silicone film/wafer laminate.

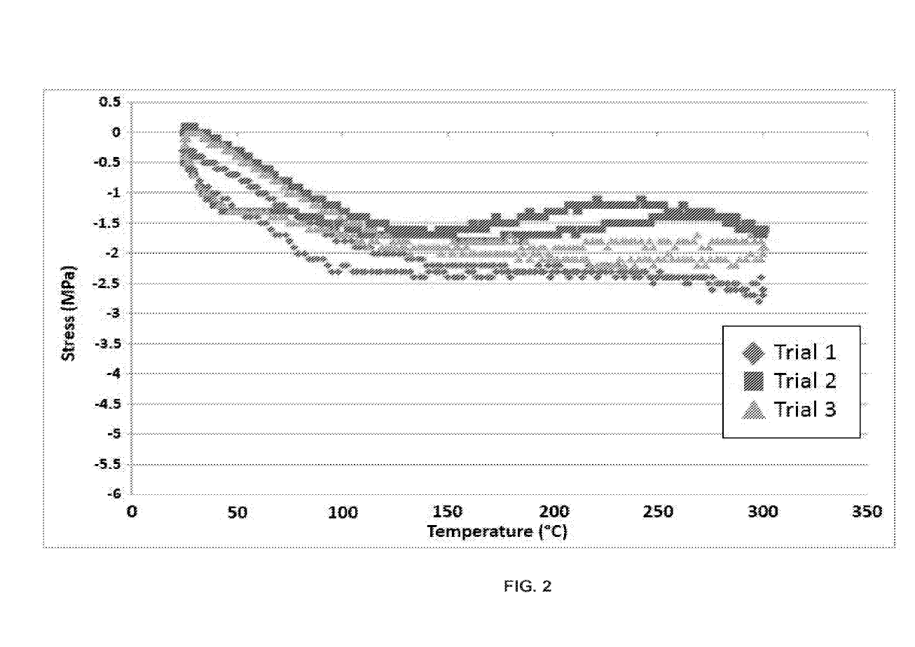

FIG. 2 is a graph plotting stress versus temperature for thermal cycling Trial 1 (diamonds), Trial 2 (squares), and Trial 3 (triangles). In FIG. 2, it may be observed that the photopatterned cured silicone film/wafer laminate may be thermal cycled between 25° C. and 300° C. (i.e., heated to 300° C., cooled back to 25° C., and repeated) shows small changes of stress of 0 megapascals (MPa) to −2.7 MPa. The photopatterned cured silicone film did not harden or crack under thermal cycling. In contrast, photopatterned films of cured organic polymers experience higher stress during thermal processing, which higher stress after hundreds of thermal cycles could possibly result in cracking and/or hardening under the foregoing thermal cycling conditions.

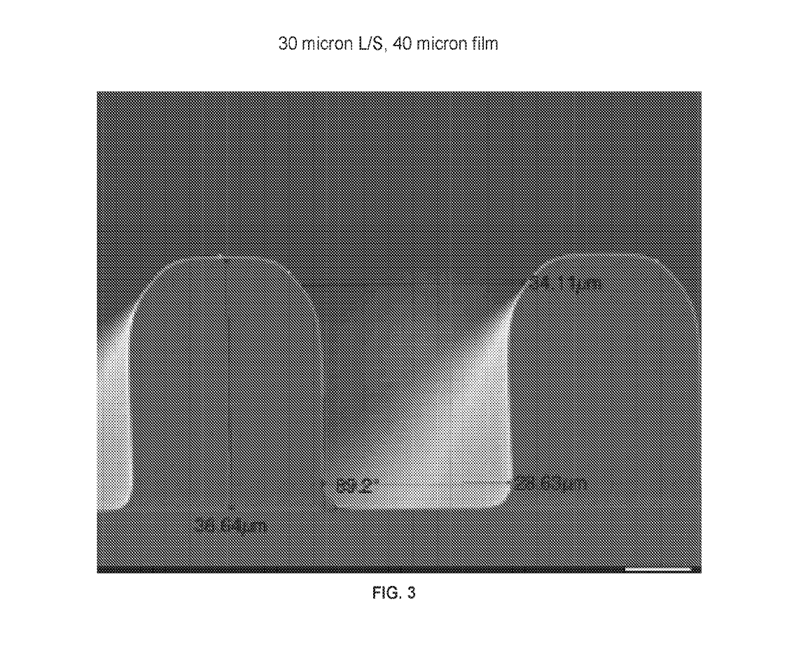

FIG. 3 is a cross-section view of a SEM image of a line space in an example of an inventive photopatterned film/wafer laminate. The laminate comprises the photopatterned film on a silicon wafer. The photopatterned film is an example of the photopatterned cured silicone film/wafer laminate prepared by the method described for FIG. 1. In FIG. 3, the pattern has a height (and thus the line spacing has a depth) of 36.64 μm. The line spacing has a width at its mouth (top, distal from the wafer) of 34.11 μm. The line space at proximal to the wafer surface (bottom) has a width of 28.63 μm and wall slope of 89.2°, nearly perpendicular to the surface of the wafer.

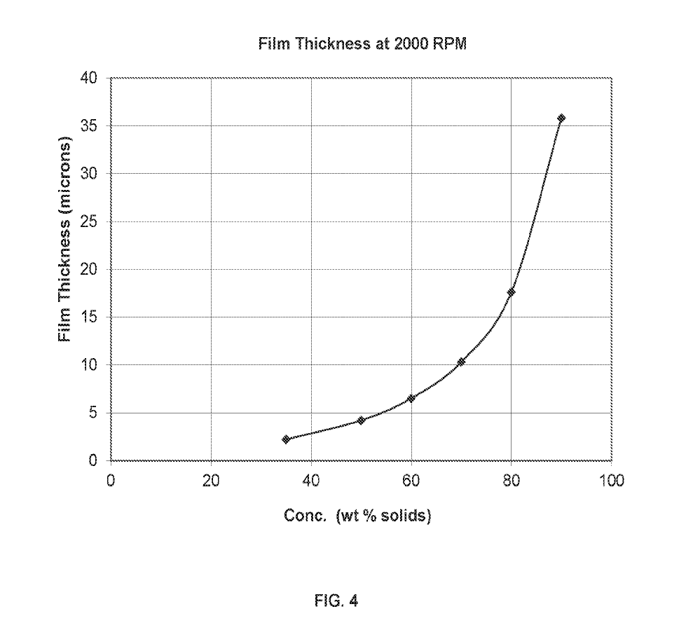

FIG. 4 is a graph of a spin curve plotting film thickness versus weight percent solids concentration at 2,000 rpm. The film thickness is about 2 μm when the solids concentration is about 35 wt %, about 4 μm when the solids concentration is about 48 wt %, about 6 μm when the solids concentration is about 60 wt %, about 10.5 μm when the solids concentration is about 69 wt %, about 17.5 μm when the solids concentration is about 80 wt %, and about 36 μm when the solids concentration is about 89 wt %.

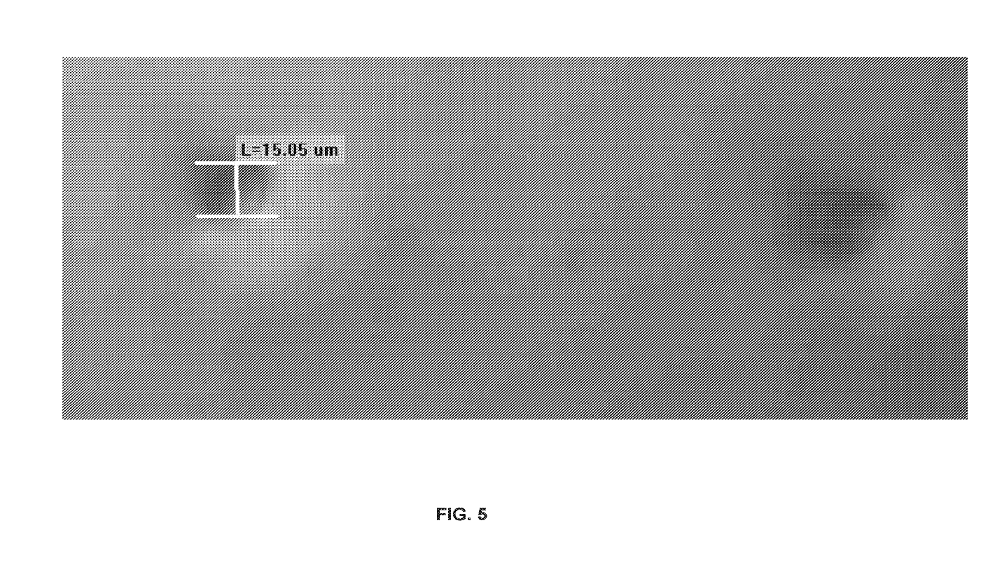

FIG. 5 is a photograph of a photopatterned cured silicone film/wafer laminate of Example 7A with imperfectly formed vias in the film. The film of Ex. 7A has a width proximal to the wafer of 15.05 μm and a depth of 31.2 μm (not indicated). The depth was measured using Interferometry.

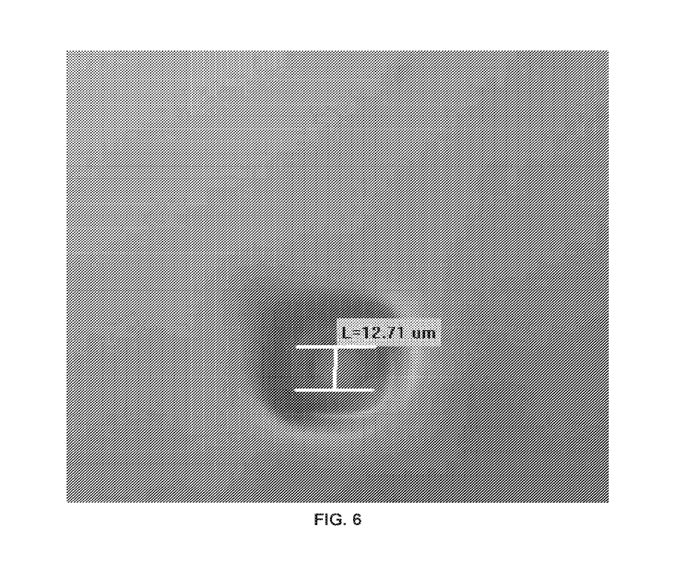

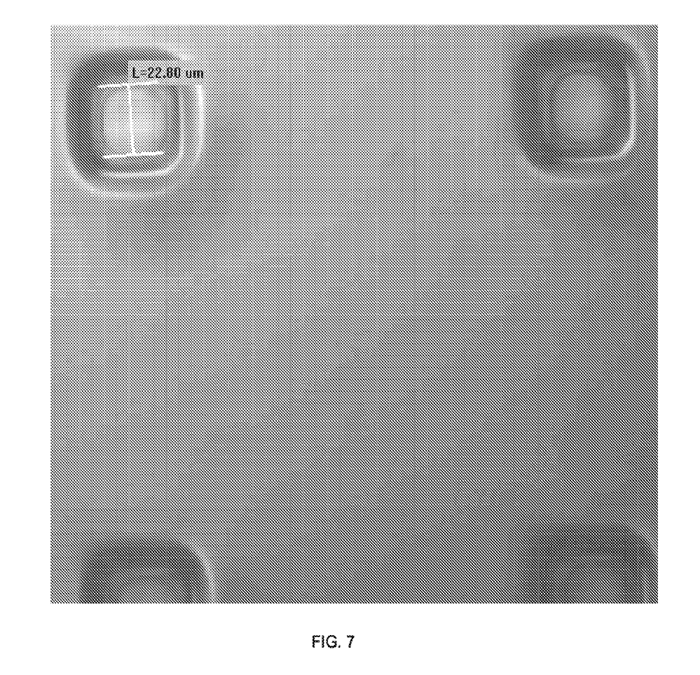

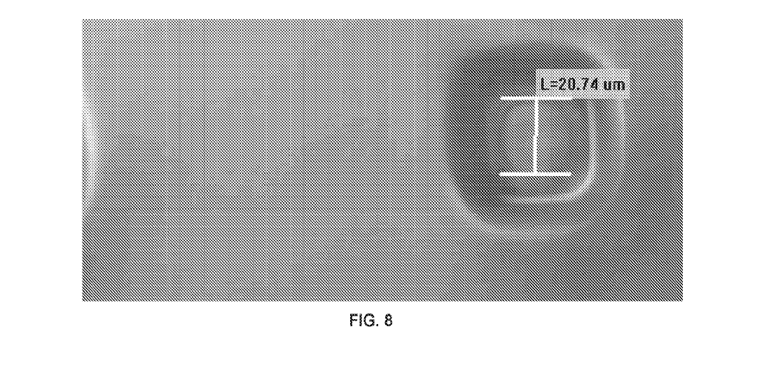

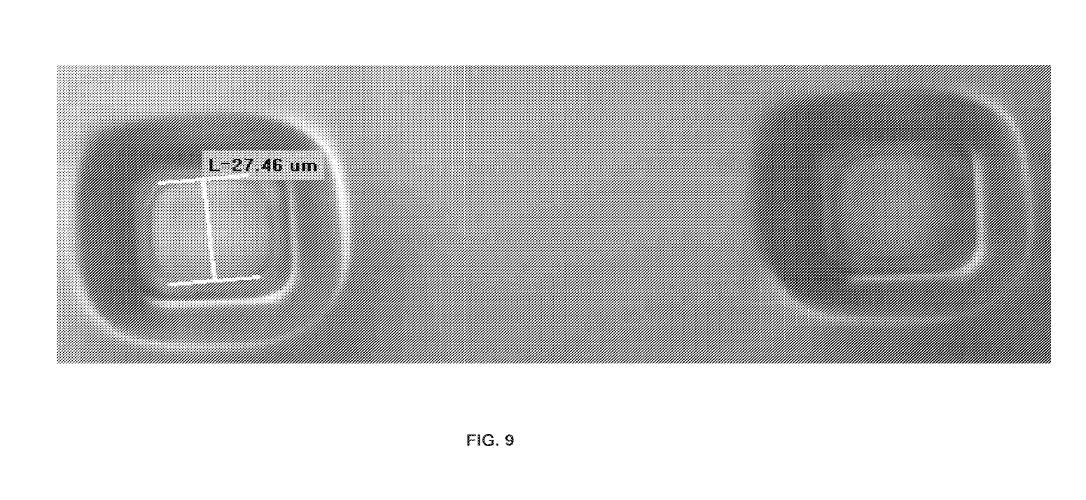

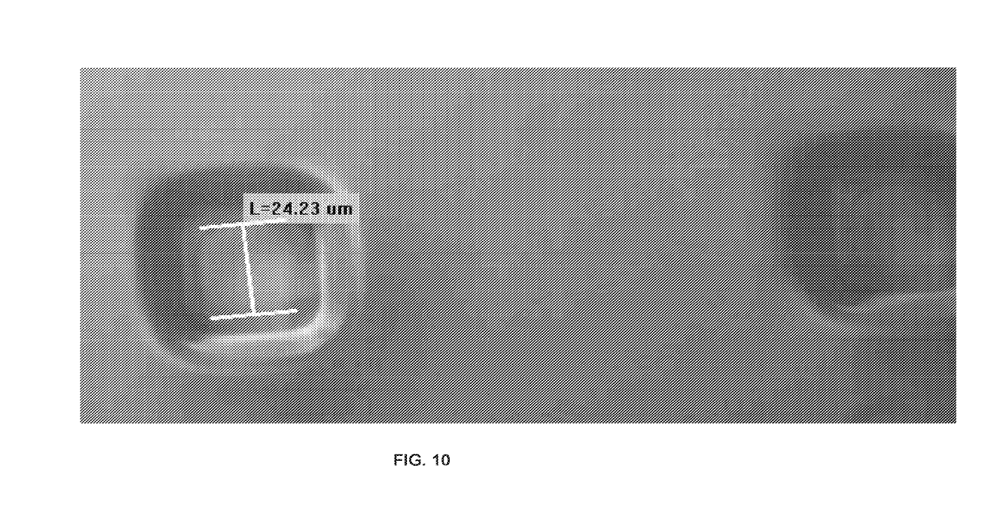

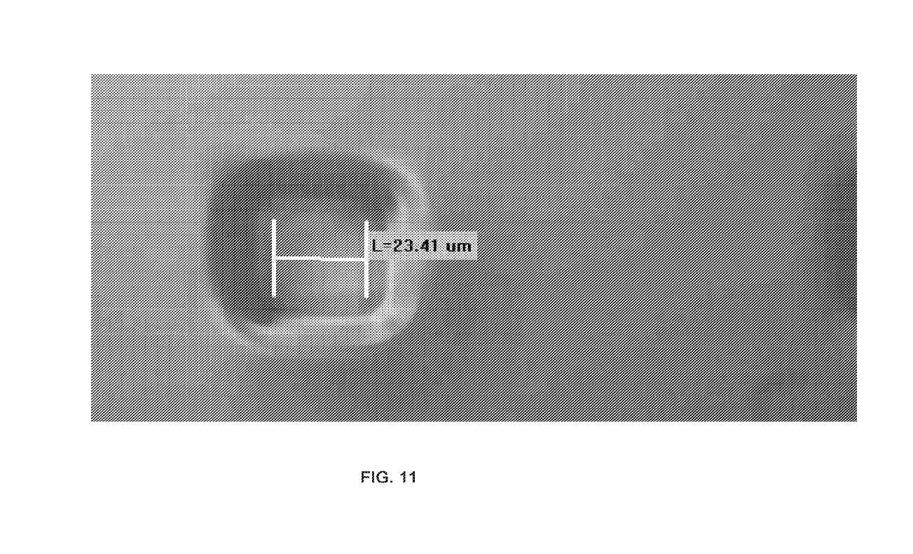

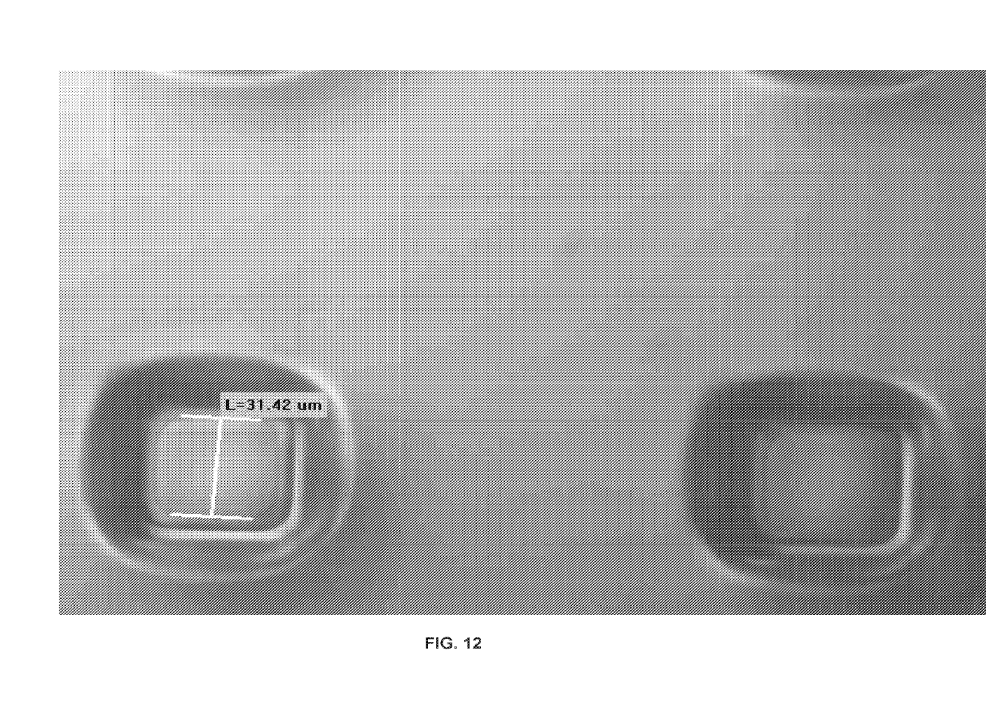

FIGS. 6 to 12 are photographs of photopatterned cured silicone film/wafer laminates of Examples 7B to 7H, respectively, with completely formed vias in the films. In FIG. 6, the film of Ex. 7B has a width proximal to the wafer of 12.71 μm and a depth of 34.4 μm (not indicated). In FIG. 7, the film of Ex. 7C has a width proximal to the wafer of 22.0 μm. In FIG. 8, the film of Ex. 7D has a width proximal to the wafer of 20.74 μm and a depth of 34.4 μm (not indicated). In FIG. 9, the film of Ex. 7E has a width proximal to the wafer of 27.46 μm and a depth of 35.3 μm (not indicated). In FIG. 10, the film of Ex. 7F has a width proximal to the wafer of 24.23 μm and a depth of 37.1 μm (not indicated). In FIG. 11, the film of Ex. 7G has a width proximal to the wafer of 23.41 μm and a depth of 39.9 μm (not indicated). In FIG. 12, the film of Ex. 7H has a width proximal to the wafer of 31.42 μm and a depth of 37.5 μm (not indicated). The depths were measured using Interferometry.

Additional embodiments and aspects are contemplated and described herein.

The inventive butyl acetate-silicone formulation and concentrated silicone formulation made therefrom independently solve a number of problems and have a number of benefits and advantages. Some problems solved herein are solvent-caused, others impurity caused, and others of unknown cause. Some benefits or advantages are illustrated by comparing the inventive formulation with a comparative formulation containing ethyl acetate, xylenes and/or mesitylene, or gamma-butyrolactone as solvent in place of the present butyl acetate. For example in a soft bake step used to remove solvent from a formulation to make a photopatternable formulation, the inventive formulation is less prone to premature drying and/or avoids or minimizes premature gelation relative to the comparative formulations. Also, the inventive butyl acetate-silicone formulation may have a longer shelf life than the comparative formulation.

Further benefits are that the inventive butyl acetate-silicone formulation and method may be used to make a film of the concentrated silicone formulation that is photopatternable and in which can be formed vias with aspect ratios greater than 1:1. The film with such aspect ratio vias may be especially useful in applications such as a redistribution dielectric layer (RDL), a stress buffer layer, or a passivation layer. Also, the film with such aspect ratio vias may be useful as optical membranes with pads to be opened. The film has sufficient dielectric strength for use as a passivation layer.

Further benefits are that in some embodiments, the inventive method further comprises a edge bead removal step using the inventive films prepared by coating (e.g., spin-coating) the butyl acetate-silicone formulation on a substrate to give a film thereof on the substrate or a film of the concentrated silicone formulation on the substrate. The edge bead removal step may be performed with the coated (e.g., spin-coated) film directly, especially with the film of the concentrated silicone formulation directly, that is without first using a soft bake step to remove the (residual amount of) butyl acetate from the coated film. In other embodiments the inventive method further comprises a step of soft baking the (residual amount of) butyl acetate out of the film before the edge bead removal step. Whether or not the butyl acetate is soft baked out, however, the resulting films after the edge bead removal step may be free of defects, even if the thickness of the resulting films is a few micrometers (e.g., from 1 to 5 μm).

Further benefits are that the inventive butyl acetate-silicone formulation and concentrated silicone formulation may have a better EH&S profile in that it may be made or purified in such a way so as to avoid or minimize concentration of cyclic siloxanes therein. In some aspects the inventive formulations may have a decreased cyclic siloxanes content of from 0 to less than 0.5 weight percent (wt %), alternatively from 0 to <0.3 wt %, alternatively from 0 to <0.2 wt %, alternatively from 0 to <0.1 wt %, alternatively 0 wt %, based on total weight of the formulation. The inventive concentrated silicone formulation has sufficient adhesiveness to certain materials, including gallium arsenide, silicon, silicon carbide, silicon oxide, or silicon nitride. In some embodiments the inventive formulation has increased adhesiveness to a silicon nitride layer disposed on a silicon wafer. The improvement in adhesiveness may be due to the inventive formulations being free of, or have a sufficiently low concentration of, an impurity that inhibits adhesion. The offending impurity may be a silicon-containing monomer or oligomer.

Further benefits are that an inventive film may be prepared from the butyl acetate-silicone formulation by applying the formulation on a substrate to form a film thereof on the substrate, soft baking the applied film to give a butyl acetate-free film on the substrate, and curing the butyl acetate-free film on the substrate to give a dielectric layer on the substrate, wherein the dielectric layer is the inventive cured silicone product. The inventive dielectric layer have an improved (i.e., greater) dielectric strength compared to dielectric strength of a comparative dielectric layer prepared from a comparative formulation having an aromatic hydrocarbon solvent such as mesitylene and/or xylenes instead of butyl acetate. Some embodiments have a combination of two or more of the foregoing advantages.

Among other uses, the butyl acetate-silicone formulation is useful for forming coatings and films. The butyl acetate-silicone formulation is also useful for preparing the concentrated silicone formulation by removing most, but not all, of the coating effective amount of butyl acetate from the butyl acetate-silicone formulation. The concentrated silicone formulation so prepared contains the residual amount of the butyl acetate. The concentrated silicone formulation may be cured to give a cured silicone product. The residual amount of the butyl acetate from the concentrated silicone formulation is carried through the curing step such that the cured silicone product retains at least some, alternatively all, the residual amount of butyl acetate. Alternatively, all of the butyl acetate is removed from the butyl acetate-silicone formulation or the concentrated silicone formulation to give a butyl acetate-free curable formulation consisting essentially of constituents (A) to (C) and optionally any one or more optional constituents (E) to (J)), but lacking (D) butyl acetate. The phrase “consisting essentially of” in this context means lacking (i.e., is free of) (D) butyl acetate; and lacking any other organic solvent having a boiling point ≦120° C.; and lacking (i.e., is free of) a thermally conductive filler. The butyl acetate-free formulation may be cured to give a cured silicone product that is free of butyl acetate. Further, the cured silicone product is resistant to cracking.

The concentrated silicone formulation may be cured via any suitable hydrosilylation curing method to give a cured silicone product. In some embodiments the concentrated silicone formulation may be cured by hydrosilylation reaction that is initiated by heating the formulation. In some embodiments, the hydrosilylation catalyst is a photoactivatable hydrosilylation catalyst and the concentrated silicone formulation may be cured by exposing (C) the photoactivatable hydrosilylation catalyst to radiation such as ultraviolet and/or visible light, thereby activating the catalyst, and heating the formulation, thereby starting the hydrosilylation curing. Upon curing the concentrated silicone formulation, a cured silicone product is prepared. Typically, the radiation is either broadband ultraviolet light or I-line (365 nm) UV light. The cured silicone product may be prepared as a standalone article or as a coating or film disposed on a substrate. The standalone article may be useful as an optical membrane in MEMS applications. The coating or film may be patterned and used as a photoresist layer on a device wafer such as a semiconductor device wafer. The invention includes additional uses and applications for the formulations, articles and devices, such as sealants, adhesives, thermal and/or electrical insulating layers, and so on.

As described above herein, the butyl acetate-silicone formulation comprises constituents (A) to (D). Constituent (A) is an organopolysiloxane containing an average, per molecule, of at least two alkenyl groups. Constituent (B) is an organosilicon compound containing an average, per molecule, of at least two silicon-bonded hydrogen atoms (SiH-functional organosilicon compound); Constituent (C) is a hydrosilylation catalyst. Constituent (D) is butyl acetate. The amounts of the constituents of the formulation may be calculated from the amounts of the constituents in the formulation after adjusting for the loss of most, but not all, butyl acetate from the coating effective amount thereof in the butyl acetate-silicone formulation to produce the residual amount of butyl acetate in the concentrated silicone formulation.

Constituent (A), the organopolysiloxane containing an average, per molecule, of at least two alkenyl groups, is also referred to herein simply as Constituent (A) or the organopolysiloxane. The organopolysiloxane may have a structure that is linear, branched, resinous, or a combination of at least two of linear, branched and resinous. For example, such a combination structure may be a so-called resin-linear organopolysiloxane. The organopolysiloxane can be a homopolymer or a copolymer. The alkenyl groups typically have from 2 to 10 carbon atoms and are exemplified by, but not limited to, vinyl, allyl, butenyl, and hexenyl. The butenyl may be 1-buten-1-yl, 1-buten-2-yl, 2-buten-1-yl, 1-buten-4-yl, or 2-methylpropen-3-yl. The hexenyl may be 1-hexen-1-yl, 1-hexen-2-yl, 2-hexen-1-yl, 1-hexen-6-yl, or 2-methylpenten-5-yl. The alkenyl groups may be located at terminal, pendant, or both terminal and pendant positions in the organopolysiloxane. The organopolysiloxane typically lacks SiH functionality such that silicon valencies other than those bonded to the alkenyl groups or to oxygen (of the siloxane portion of the organopolysiloxane) are bonded to saturated and/or aromatic organic groups, i.e., organic groups, represented by R¹, other than unsaturated aliphatic groups. The saturated and/or aromatic organic groups R¹ in the organopolysiloxane are independently selected from monovalent hydrocarbon and monovalent halogenated hydrocarbon groups free of aliphatic unsaturation. Each R¹ typically independently has from 1 to 20, alternatively from 1 to 10, alternatively from 1 to 6 carbon atoms. Examples of R¹ groups are alkyl, cycloalkyl, aryl, arylalkyl, alkylaryl, and halogenated substituted derivatives thereof. Each halogen of the halogenated substituted derivative independently is fluoro, chloro, bromo, or iodo; alternatively fluoro, chloro, or bromo; alternatively fluoro or chloro; alternatively fluoro; alternatively chloro. Examples of alkyl are methyl, ethyl, propyl, pentyl, octyl, undecyl, and octadecyl. Examples of cycloalkyl are cyclopentyl and cyclohexyl. Examples of aryl are phenyl and naphthyl. Examples of alkylaryl are tolyl and xylyl. Examples of arylalkyl are benzyl and 2-phenylethyl. Examples of the halogenated substituted derivatives thereof are 3,3,3-trifluoropropyl, 3-chloropropyl, and dichlorophenyl. At least 50 mole percent (mol %), alternatively at least 80 mol %, of the R¹ groups may be methyl.

The organopolysiloxane may be a single organopolysiloxane or a mixture of two or more organopolysiloxanes that differ in at least one of the following properties: structure, viscosity (kinematic, 25° C.), average molecular weight (number average or weight average), siloxane unit composition, and siloxane unit sequence.

Constituent (A) the organopolysiloxane may have a kinematic viscosity at 25° C. that varies with molecular weight and structure of the organopolysiloxane. The kinematic viscosity may be from 0.001 to 100,000 pascal-seconds (Pa·s), alternatively from 0.01 to 10,000 Pa·s, alternatively from 0.01 to 1,000 Pa·s, alternatively from 1 to 500 Pa·s.

Examples of Constituent (A) that are suitable linear organopolysiloxanes are polydiorganosiloxanes having any one of the following formulas (1) to (6): M^{Vi}DₐM^{Vi} (1); M^{Vi}D_{0.25a}D^{Ph}_{0.75a}M^{Vi} (2); M^{Vi}D_{0.95a}D^{2Ph}_{0.05a}M^{Vi} (3); M^{Vi}D_{0.98a}D^{Vi}_{0.02a}M^{Vi} (4); MD_{0.95a}D^{Vi}_{0.05a}M (5); and M^{Ph,Vi}DₐM^{Ph,Vi} (6); wherein subscript a has a value such that the kinematic viscosity of the polydiorganosiloxane is from 0.001 to 100,000 Pa·s.; each M unit is of formula [(Si(CH₃)₃O_{1/2}]; each M^{Vi} unit is a vinyl-monosubstituted M unit and is of formula [(Si(CH₃)₂(CH═CH₂)O_{1/2}]; each M^{Ph,Vi} unit is a phenyl-monosubstituted and vinyl-monosubstituted M unit and is of formula [(Si(CH₃)(Ph)(CH═CH₂)O_{1/2}]; each D unit is of formula [(Si(CH₃)₂O_{2/2}]; each D^{Vi} unit is a vinyl-monosubstituted D unit and is of formula [(Si(CH₃)(CH═CH₂)O_{2/2}]; each D^{Ph} unit is a phenyl-monosubstituted D unit and is of formula [(Si(CH₃)(Ph)O_{2/2}]; each D^{2Ph} unit is a phenyl-disubstituted D unit and is of formula [(Si(Ph)₂O_{2/2}].

Examples of Constituent (A) that are branched organopolysiloxanes are polydiorganosiloxanes having any one of the following formulas (1) to (6): M^{Vi}DD′DₐM^{Vi} (1); M^{Vi}D′D_{0.25a}DD′D^{Ph}_{0.75a}M^{Vi} (2); M^{Vi}DD′D_{0.95a}DD′D^{2Ph}_{0.05a}M^{Vi} (3); M^{Vi}DD′D_{0.98a}DD′D^{Vi}_{0.02a}M^{Vi} (4); MDD′D_{0.95a}DD′D^{Vi}_{0.05a}M (5); and M^{Ph,Vi}DD′DₐM^{Ph,Vi} (6); wherein subscript a has a value such that the kinematic viscosity of the polydiorganosiloxane is from 0.001 to 100,000 Pa·s.; each M unit is of formula [(Si(CH₃)₃O_{1/2}]; each M^{Vi} unit is a vinyl-monosubstituted M unit and is of formula [(Si(CH₃)₂(CH═CH₂)O_{1/2}]; each M^{Ph,Vi} unit is a phenyl-monosubstituted and vinyl-monosubstituted M unit and is of formula [(Si(CH₃)(Ph)(CH═CH₂)O_{1/2}]; each D unit is of formula [(Si(CH₃)₂O_{2/2}]; each D′ unit is of formula [Si(CH₃)RO_{2/2}], where each R independently is —CH₃, —(CH₂)ₙCH₃, —(CH₂)ₙCH═CH₂, —(O—Si(Me₂))ₙ—(OSi(Me)(H))ₘ—O—SiMePhCh=CH₂, —(O—Si(Me)(H))ₙ—O—Si(Me)(Ph)(CH═CH₂), or —(O—Si(Me₂))ₙ—O— Si(Me)(Ph)(CH═CH₂), and subscripts n and m independently are integers from 1 to 9; each D^{Vi} unit is a vinyl-monosubstituted D unit and is of formula [(Si(CH₃)(CH═CH₂)O_{2/2}]; each D^{Ph} unit is a phenyl-monosubstituted D unit and is of formula [(Si(CH₃)(Ph)O_{2/2}]; and each D^{2Ph} unit is a phenyl-disubstituted D unit and is of formula [(Si(Ph)₂O_{2/2}]. Expressions such as “—(O—Si(Me)(H))ₙ—O—Si(Me)(Ph)(CH═CH₂)” may be equivalently written as “—(O—Si(Me,H))ₙ—O—Si(Me,Ph,CH═CH₂).”

Examples of Constituent (A) that are suitable organopolysiloxanes resins are alkenyl-substituted MQ resins, alkenyl-substituted TD resins, alkenyl-substituted MT resins, alkenyl-substituted MTD resins, and combinations of any two or more thereof. The organopolysiloxane may be the organopolysiloxane resin, wherein the organopolysiloxanes resin is the alkenyl-substituted MQ resin, alkenyl-substituted TD resin, alkenyl-substituted MT resin, or alkenyl-substituted MTD resin; alternatively the alkenyl-substituted TD resin, alkenyl-substituted MT resin, or alkenyl-substituted MTD resin; alternatively the alkenyl-substituted MQ resin, alkenyl-substituted MT resin, or alkenyl-substituted MTD resin; alternatively the alkenyl-substituted MQ resin; alternatively the alkenyl-substituted TD resin; alternatively the alkenyl-substituted MT resin; alternatively the alkenyl-substituted MTD resin.

The organopolysiloxane may comprise the alkenyl-substituted MTD resin. The alkenyl-substituted MTD resin consists essentially of M-type units, T-type units, D-type units, and at least one of M^{alkenyl}-type units, D^{alkenyl}-type units, and T^{alkenyl} units. That is, the phrase “consists essentially of” in this context means the alkenyl-substituted MTD resin is substantially free of (i.e., from 0 to <0.10 mole fraction) or completely free of (i.e., 0.00 mole fraction) Q units. The M-type units are of formula [(Si(R¹)₃O_{1/2}]ₘ₁, wherein subscript m1 is a mole fraction of the M-type units in the resin. The M^{alkenyl}-type units are of formula [(alkenyl)(R¹)₂SiO_{1/2}]ᵥ, wherein subscript v is a mole fraction of the M^{alkenyl}-type units in the resin. The D-type units are of formula [(R¹)₂SiO_{2/2}]_{d}, wherein subscript d is a mole fraction of the D-type units in the resin. The D^{alkenyl}-type units are of formula [(R¹)(alkenyl)SiO_{2/2}]_{d}, wherein subscript d is a mole fraction of the D^{alkenyl}-type units in the resin. The T-type units are of formula [R¹SiO_{3/2}]ₜ, wherein subscript t is a mole fraction of the T-type units in the resin. The T^{alkenyl}-type units are of formula [alkenylSiO_{3/2}]ₜ, wherein subscript t is a mole fraction of the T-type units in the resin.

The organopolysiloxane may comprise the alkenyl-substituted MT resin. The alkenyl-substituted MT resin consists essentially of M-type units, T-type units, and at least one of M^{alkenyl}-type units and T^{alkenyl} units. That is, the phrase “consists essentially of” in this context means the alkenyl-substituted MT resin is substantially free of (i.e., from 0 to <0.10 mole fraction) or completely free of (i.e., 0.00 mole fraction) D units and Q units. The M-type units, M^{alkenyl}-type units, T-type units, and T^{alkenyl}-type units independently are as described above.

The organopolysiloxane may comprise the alkenyl-substituted TD resin. The alkenyl-substituted TD resin consists essentially of T-type units, D-type units, and at least one of D^{alkenyl}-type units and T^{alkenyl} units. That is, the phrase “consists essentially of” in this context means the alkenyl-substituted TD resin is substantially free of (i.e., from 0 to <0.10 mole fraction) or completely free of (i.e., 0.00 mole fraction) M and Q units. The D-type units, D^{alkenyl}-type units, T-type units, and T^{alkenyl}-type units are as defined above.

The organopolysiloxane may comprise the alkenyl-substituted MQ resin. The alkenyl-substituted MQ resin consists essentially of M-type units, M^{alkenyl}-type units, and Q units. That is, the phrase “consists essentially of” in this context means the alkenyl-substituted MQ resin is substantially free of (i.e., from 0 to <0.10 mole fraction) or completely free of (i.e., 0.00 mole fraction) T-type units and Q units. The M-type units and M^{alkenyl}-type units are as defined above. The Q units are of formula [SiO_{4/2}]_{q}, wherein subscript q is a mole fraction of the Q units in the resin. The mole ratio of the M-type units to the Q units may be from 0.6 to 1.9.

In some embodiments constituent (A) is the organopolysiloxane resin and the organopolysiloxane resin is the alkenyl-substituted MQ resin and the alkenyl-substituted MQ resin is a vinyl-substituted MQ resin. In such embodiments the vinyl-substituted MQ resin may comprise M units, vinyl-substituted M units abbreviated as M^{Vi} units, Q units, and hydroxyl-functional T units abbreviated as T^{OH} units. Using conventional nomenclature, the M^{Vi} units are of formula [(H₂C═C(H))(CH₃)₂SiO_{1/2}]ᵥ, wherein subscript v is a mole fraction of the M^{Vi} units in the resin. The Q units are of formula [SiO_{4/2}]_{q}, wherein subscript q is a mole fraction of the Q units in the resin. The M units are of formula [(Si(CH₃)₃O_{1/2}]ₘ₁, wherein subscript m1 is a mole fraction of the M units in the resin. The T^{OH} units are of formula [HOSiO_{3/2}]ₜ, wherein subscript t is a mole fraction of the T^{OH} units in the resin. The subscript v is from 0.03 to 0.08; subscript m1 is from 0.30 to 0.50; subscript q is from 0.30 to 0.60; subscript t is from 0.04 to 0.09; with the proviso that the sum of subscripts v+q+m1+t=1. For example, the vinyl-functional MQ resin may be of the following formula: M^{Vi}_{0.055±0.005}Q_{0.45±0.05}T^{OH}_{0.065±0.005}M_{0.40±0.05}.

The proviso that the sum of subscripts v+q+m1+t=1 applies to each of the foregoing alternative embodiments of the vinyl-functional MQ resin. In any particular embodiment, should the sum of v+q+m1+t be inadvertently >1, then the value for q shall be decreased to equal 1 v m1−t. In any particular embodiment, should the sum of v+q+m1+t be <1, then the resin may further comprise a mole fraction i wherein v+q+m1+t+i=1, wherein i shall be a mole fraction of a hydroxyl functional M, D and/or T unit abbreviated M^{OH}, T_{OH}, and/or D_{OH}, wherein the M_{OH}, T_{OH}, and/or D_{OH} unit(s) may be an impurity carried through from the preparation of the resin.

The organopolysiloxane resin may contain an average of from 3 to 30 mol % of alkenyl groups. The mol % of alkenyl groups in the resin is the ratio of the number of moles of alkenyl-containing siloxane units in the resin to the total number of moles of siloxane units in the resin, multiplied by 100.

The organopolysiloxane may be prepared by methods well known in the art. For example, the alkenyl-substituted MQ resin may be prepared by preparing a resin copolymer by the silica hydrosol capping process of U.S. Pat. No. 2,676,182 to Daudt et al., and then treating the resin copolymer with at least an alkenyl-containing endblocking reagent to give the organopolysiloxane resin. Examples of the alkenyl-containing endblocking reagent are silazanes, siloxanes, and silanes such as those exemplified in U.S. Pat. No. 4,584,355 to Blizzard et al.; U.S. Pat. No. 4,591,622 to Blizzard et al.; and U.S. Pat. No. 4,585,836 to Homan et al. A single endblocking reagent or a mixture of two or more such reagents may be used to prepare the alkenyl-substituted MQ resin.

The process of Daudt et al. involves reacting a silica hydrosol under acidic conditions with a hydrolyzable triorganosilane such as trimethylchlorosilane (an example of a silicon monomer), an organosiloxane such as hexamethyldisiloxane (an example of a silicon oligomer), or a mixture thereof; and then recovering a resin copolymer having M and Q units. The resin copolymer generally contains from 2 to 5 weight percent of silicon-bonded hydroxyl (SiOH) groups. Reacting the resin copolymer with the alkenyl-containing endblocking reagent (e.g., (H₂C═C(H))(CH₃)₂SiCl), or with a mixture of the alkenyl-containing endblocking reagent and an endblocking agent free of aliphatic substitution (e.g., a mixture of (H₂C═C(H))(CH₃)₂SiCl and (CH₃)₃SiCl) then gives the alkenyl-substituted MQ resin having from 0 to less than 2 wt % SiOH groups and typically from 3 to 30 mol % alkenyl groups (e.g., H₂C═C(H)—).

Constituent (B) of the butyl acetate-silicone formulation and concentrated silicone formulation is the organosilicon compound containing an average, per molecule, of at least two silicon-bonded hydrogen atoms, which is also referred to herein as Constituent (B) or the SiH-functional organosilicon compound. The silicon-bonded hydrogen atoms may be located at terminal, pendant or both terminal and pendant positions in the SiH-functional organosilicon compound. The SiH-functional organosilicon compound may be a single compound or a mixture of two or more such compounds that differ in at least one of the following properties: structure, average molecular weight (number or weight average), viscosity (kinematic, 25° C.), silane unit composition, siloxane unit composition, and unit sequence.

The SiH-functional organosilicon compound may be an organohydrogensilane or an organohydrogensiloxane. The organohydrogensilane may be an organomonosilane, organodisilane, organotrisilane, or organopolysilane containing organic groups and SiH groups. The organohydrogensiloxane may be an organohydrogendisiloxane, organohydrogentrisiloxane, or organohydrogenpolysiloxane. For example, the SiH-functional organosilicon compound may be an organohydrogensiloxane, alternatively an organohydrogenpolysiloxane. The structure of the SiH-functional organosilicon compound may be linear, branched, cyclic, or resinous; alternatively linear; alternatively branched; alternatively cyclic; alternatively resinous. At least 50 mol % of the organic groups in the SiH-functional organosilicon compound may be methyl, and any remaining organic groups may be ethyl and/or phenyl.

Examples of suitable organohydrogensilanes for use as the SiH-functional organosilicon compound are organomonosilanes such as diphenylsilane and 2-chloroethylsilane; organodisilanes such as 1,4-bis(dimethylsilyl)benzene, bis[(4-dimethylsilyl)phenyl] ether, and 1,4-dimethyldisilylethane; organotrisilanes such as 1,3,5-tris(dimethylsilyl)benzene and 1,3,5-trimethyl-1,3,5-trisilane; and organopolysilanes such as poly(methylsilylene)phenylene and poly(methylsilylene)methylene.

Examples of suitable organohydrogensiloxanes for use as the SiH-functional organosilicon compound are disiloxanes such as 1,1,3,3-tetramethyldisiloxane and 1,1,3,3-tetraphenyldisiloxane; trisiloxanes such as phenyltris(dimethylsiloxy)silane and 1,3,5-trimethylcyclotrisiloxane; and polysiloxanes such as a trimethylsiloxy-terminated poly(methylhydrogensiloxane), a trimethylsiloxy-terminated poly(dimethylsiloxane/methylhydrogensiloxane), a dimethylhydrogensiloxy-terminated poly(methylhydrogensiloxane), and a MDQ-type resin consisting essentially of H(CH3)₂SiO_{1/2} units, (CH₃)₂SiO_{2/2} units, and SiO_{4/2} units. That is, in this context the phrase “consisting essentially of” means the MDQ-type resin is substantially free of (i.e., from 0 to <0.10 mole fraction) or completely free of (i.e., 0.00 mole fraction) T units and M and D units other than the respective H(CH3)₂SiO_{1/2} units and (CH₃)₂SiO_{2/2} units.

In some embodiments constituent (B) is a SiH-functional organosilicon compound that comprises M units, D units, and SiH-functional D units abbreviated as D^{H} units. Using conventional nomenclature, the D^{H} units are of formula [(H))(CH₃)SiO_{2/2}]ₕ, wherein subscript h is a mole fraction of the D^{H} units in the linear silicone. The D units are of formula [(CH₃)₂SiO_{2/2}]_{d}, wherein subscript d is a mole fraction of the D units in the linear silicone. The M units are of formula [(Si(CH₃)₃O_{1/2}]₂, wherein subscript m2 is a mole fraction of the M units in the linear silicone. The subscript h is from 0.06 to 0.11; subscript d is from 0.75 to 0.97; subscript m2 is from 0.015 to 0.020; with the proviso that the sum of subscripts h+d+m2=1.

The proviso that the sum of subscripts h+d+m2=1 applies to each of the foregoing alternative embodiments of h, d, and m2 and to the ad rem formulas. In any particular embodiment, should the sum of h+d+m2 inadvertently be >1, then the value for d shall be decreased to equal 1 h m2. In any particular embodiment, should the sum of h+d+m2<1, then the linear silicone may further comprise a mole fraction i wherein h+d+m2+j=1, wherein j shall be a mole fraction of a hydroxyl functional M, D and/or T unit abbreviated M^{OH}, T^{OH}, and/or D^{OH}, wherein the M^{OH}, T^{OH}, and/or D^{OH} unit(s) may be an impurity carried through from the preparation of the linear silicone. For example, the SiH-functional linear silicone may be of the following formula: D^{Me,H}_{0.085±0.005}D_{0.90±0.05}M_{0.015±0.005}.

Methods of preparing constituent (B) the SiH-functional organosilicon compound are well known in the art. For example, organopolysilanes may be prepared by a reaction of organochlorosilanes in a hydrocarbon solvent in the presence of sodium metal or lithium metal (an example of the so-called Wurtz reaction). Organopolysiloxanes may be prepared by hydrolysis and condensation of organohalosilanes.

Each unit subscript described herein (e.g., m1, m2, d, h, i, j, v, t, q, and the like) is independently defined. Each R¹ described herein independently is as defined above for the organopolysiloxane. To ensure compatibility of constituents (A) and (B), the predominant R¹ in each constituent (A) and (B) is of the same type (e.g., predominantly alkyl or predominantly aryl). In some embodiments the predominant R¹ group in each constituent (A) and (B) is alkyl, alternatively methyl. At least 50 mole percent (mol %), alternatively at least 80 mol %, of the R¹ groups may be methyl. The remaining R¹ groups, if any, may be ethyl and/or phenyl. The alkenyl groups are as defined above for the organopolysiloxane. Typically each alkenyl group independently is vinyl, allyl, 1-buten-4-yl, or 1-hexen-6-yl; alternatively vinyl, allyl, or 1-buten-4-yl; alternatively vinyl or allyl; alternatively vinyl or 1-buten-4-yl; alternatively vinyl; alternatively allyl; alternatively 1-buten-4-yl; alternatively 1-hexen-6-yl.

The amount of constituent (B) in the concentrated silicone formulation is a concentration sufficient to cure the formulation. The formulation may be considered to be cured by the extent of hydrosilylation reaction between the alkenyl groups of constituent (A) and the SiH groups of constituent (B) in a cured silicone product prepared therefrom. The concentration of constituent (B) in the formulation may be readily adjusted by a person of ordinary skill in the art to obtain a desired extent of cure in the cured silicone product. Typically, the concentration of constituent (B) in the formulation is sufficient to provide from 0.5 to 3, alternatively from 0.7 to 1.2, SiH groups per alkenyl group of constituent (A). When the sum of the average number of alkenyl groups per molecule of constituent (A) and the average number of silicon-bonded hydrogen atoms per molecule of constituent (B) is greater than four, crosslinking occurs and the cured silicone product may be characterized by an extent of crosslinking or crosslink density therein. All other things being equal, as the sum is increased (e.g., from >4 to 4.5, 5, or 6, such as by selecting embodiments of constituents (A) and (B) with higher average numbers of alkenyl groups per molecule and higher numbers of SiH groups per molecule, respectively), the extent of crosslinking or crosslink density in the cured silicone product prepared therefrom is increased. Separately, all other things being equal, as the concentration of constituent (B) in the formulation is increased, the extent of crosslinking or crosslink density in the cured silicone product prepared therefrom is increased. The sum and/or concentration may be readily adjusted by a person of skill in the art to achieve a desire extent of crosslinking in the cured silicone product.

The constituents (A) and (B) may be proportioned in the concentrated silicone formulation (and thus in the butyl acetate-silicone formulation) in such a way so as to configure the formulation with a SiH-to-alkenyl ratio (e.g., a SiH-to-vinyl molar ratio, SiH/Vi ratio). The SiH-to-alkenyl ratio (e.g., SiH/Vi ratio) may be measured using infrared (IR) or proton nuclear magnetic resonance (¹H-NMR) spectroscopy, e.g., using an Agilent 400-MR NMR spectrophotometer at 400 megahertz (MHz). The formulation may be proportioned to any desired SiH-to-alkenyl ratio (e.g., SiH/Vi ratio), e.g., from 10⁻⁷ to 10⁷. The SiH-to-alkenyl ratio may be tailored for a particular application or use. For example for photopatterning uses, the SiH-to-alkenyl ratio (e.g., SiH/Vi ratio) may be from 0.1 to 3, alternatively from 0.1 to 2, alternatively from 0.2 to 1.5.

The SiH-to-alkenyl ratio (e.g., SiH/Vi ratio) may be varied from formulation to formulation example for photopatterning uses so as to enable opening of vias of different widths in films of different thicknesses of the formulations. The vias may be formed in the films using the photopatterning method. For example, when the film of the concentrated silicone formulation is 40 μm thick, the SiH-to-alkenyl ratio (e.g., SiH/Vi ratio) may be from 0.65 to 1.05, alternatively from 0.70 to 1.00, alternatively from 0.72 to 0.95.

Constituent (C) of the butyl acetate-silicone formulation and concentrated silicone formulation is a hydrosilylation catalyst, typically a photoactivatable hydrosilylation catalyst. The butyl acetate-silicone formulation also comprises the hydrosilylation catalyst, typically the photoactivatable hydrosilylation catalyst. The hydrosilylation catalysts, other than the photoactivatable hydrosilylation catalyst, may be any hydrosilylation catalyst capable of catalyzing the hydrosilylation of component (A) with component (B) upon heating of the formulation. The photoactivatable hydrosilylation catalyst may be any hydrosilylation catalyst capable of catalyzing the hydrosilylation of component (A) with component (B) upon/after exposing the catalyst to radiation having a wavelength comprising I-line radiation (e.g., 365 nm), and heating of the formulation. Typically, the radiation is either broadband ultraviolet light or only I-line (365 nm) UV light. The formulation may be heated before, concurrently with, or after the exposing to radiation step. Typically, the hydrosilylation catalyst comprises a metal, e.g., a platinum group metal. The metal may be palladium, platinum, rhodium, ruthenium, or a combination of any two or more thereof. The metal may be palladium, alternatively platinum, alternatively rhodium, alternatively ruthenium, alternatively a combination of platinum and at least one of palladium, rhodium, and ruthenium. The metal may be part of a metal-ligand complex. The ligand of the metal-ligand complex may be any monodentate ligand, multidentate ligand, or a combination thereof.

In some embodiments the hydrosilylation catalyst may be a Rh catalyst. Such a Rh catalyst is [Rh(cod)₂]BF₄ wherein cod is 1,5-cyclooctadiene, Wilkinson's catalyst (Rh(PPh₃)₃Cl wherein Ph is phenyl), Ru(η⁶-arene)Cl₂]₂ wherein arene is benzene or para-cymene, wherein para-cymene is 1-methyl-4-(1-methylethyl)benzene, a Grubb's catalyst (e.g., Ru═CHPh(PPh₃)₂Cl₂ wherein Ph is phenyl), or [Cp*Ru(CH₃CN)₃]PF₆) wherein Cp* is 1,2,3,4,5-pentamethylcyclopentadiene anion. Alternatively, the hydrosilylation catalyst may be a Pt catalyst. Examples of the Pt catalyst is Speier's catalyst (H₂PtCl₆; U.S. Pat. No. 2,823,218 and U.S. Pat. No. 3,923,705) or Karstedt's catalyst (Pt[H₂C═CH—Si(CH₃)₂]₂O); U.S. Pat. No. 3,715,334 and U.S. Pat. No. 3,814,730). Alternatively platinum catalysts include, but are not limited to, the reaction product of chloroplatinic acid and an organosilicon compound containing terminal aliphatic unsaturation, including the catalysts described U.S. Pat. No. 3,419,593. Alternatively, the hydrosilylation catalysts include Pt complexes with bidentate ligands such as 1,3-butadiene, alternatively acetylacetonate. Hydrosilylation catalysts also include neutralized complexes of platinum chloride and divinyl tetramethyl disiloxane, as described in U.S. Pat. No. 5,175,325. Also, suitable hydrosilylation catalysts are described in U.S. Pat. No. 3,159,601; U.S. Pat. No. 3,220,972; U.S. Pat. No. 3,296,291; U.S. Pat. No. 3,516,946; U.S. Pat. No. 3,989,668; U.S. Pat. No. 4,784,879; U.S. Pat. No. 5,036,117; U.S. Pat. No. 5,175,325; and EP 0 347 895 B1.

Examples of suitable photoactivatable hydrosilylation catalysts are those described in U.S. Pat. No. 6,617,674 B2, column 6, line 65, to column 7, line 25; which catalysts are hereby incorporated herein by reference. Some of the photoactivatable hydrosilylation catalysts described therein are also described in the preceding paragraph. The photoactivatable hydrosilylation catalysts may be prepared by methods well known in the art as described in U.S. Pat. No. 6,617,674 B2, column 7, lines 39 to 48.

The catalytic amount of (C) the hydrosilylation catalyst used in the concentrated silicone formulation may be characterized as any atomic amount greater than 0 parts per million (ppm) of the metal derived from the hydrosilylation catalyst. The atomic amount of the metal may be from greater than 0 to 1000 ppm based on total weight of the concentrated silicone formulation. The atomic amount of the metal may be from 0.1 to 500 ppm, alternatively from 0.5 to 200 ppm, alternatively from 0.5 to 100 ppm, alternatively from 1 to 25 ppm. The metal may be any one of the platinum group metals, e.g., platinum.

Constituent (D) of the butyl acetate-silicone formulation and concentrated silicone formulation, is butyl acetate, which has the structural formula CH₃C(═O)OCH₂CH₂CH₂CH₃ and a boiling point (b.p.) of 124° C. to 126° C. Butyl acetate is used in a coating effective amount in the butyl acetate-silicone formulation. As described later, the use of the term “coating effective amount” does not limit the method of applying the formulation to a substrate to any particular coating method (e.g., does not limit the applying to only spin-coating) and does not limit the shape or form of applied formulation to only a coating or a film.

The coating effective amount of butyl acetate in the butyl acetate-silicone formulation may be from 5 to 75 wt %, alternatively from 10 to 60 wt %, alternatively from 15 to 55 wt %, alternatively from 20 to 50 wt %, alternatively from 10 to 30 wt %, alternatively from 30 to 50 wt %, alternatively 12±2 wt %, alternatively 14±2 wt %, alternatively 16±2 wt %, alternatively 18±2 wt %, alternatively 20±2 wt %, alternatively 25±2 wt %, alternatively 30±2 wt %, alternatively 35±2 wt %, alternatively 40±2 wt %, alternatively 45±2 wt %, alternatively 50±2 wt %, alternatively 55±2 wt %, alternatively 60±2 wt %, alternatively 65±2 wt, all based on total weight of the formulation.

The coating effective amount of butyl acetate in the butyl acetate-silicone formulation may be a concentration of the compound of structural formula CH₃C(═O)OCH₂CH₂CH₂CH₃ that enables the butyl acetate-silicone formulation to be coated (e.g., spin-coated) on a device wafer such as a semiconductor device wafer (e.g., any one of the wafers described earlier) to produce a coating or film having a thickness from 0.1 to 200 micrometers (μm). For example, the thickness of the coating or film that may be obtained using the butyl acetate-silicone formulation may be from 0.2 to 175 μm; alternatively from 0.5 to 150 μm; alternatively from 0.75 to 100 μm; alternatively from 1 to 75 μm; alternatively from 2 to 60 μm; alternatively from 3 to 50 μm; alternatively from 4 to 40 μm; alternatively any one of 1, 2, 3, 4, 5, 6, 7, 8, 9, 10, 15, 20, 25, 30, 35, 40, 45, 50, 60, 70, 75, 80, 90, 100, 150, 175, and 200 μm.

In spin-coating the butyl acetate-silicone formulation on a device wafer, the spin-coating may be done at a maximum spin speed and for a spin time sufficient to obtain a film of the butyl acetate-silicone formulation of the above-mentioned thickness. The maximum spin speed may be from 400 rpm to 5,000 rpm, alternatively from 500 rpm to 4,000 rpm, alternatively from 800 rpm to 3,000 rpm.

In spin-coating the butyl acetate-silicone formulation on a device wafer, the spin time may be from 0.5 seconds to 10 minutes. The spin time may be fixed, e.g., kept constant at from 30 seconds to 2 minutes, and a person of ordinary skill in the art using a conventional spin-coater apparatus may then readily adjust the spin speed for a particular concentration of butyl acetate to obtain a particular thickness of the film of the butyl acetate-silicone formulation. For example, the spin time may be kept constant at from 30 seconds to 2 minutes and the butyl acetate concentration in the butyl acetate-silicone formulation may be prepared in the lower half of its range (i.e., from 5 to 35 wt %), and then the spin speed may be set in the bottom half of its range (i.e., from 800 to 1900 rpm, that is relatively slower) for forming thicker films (i.e., films of thickness from 50 to 100 μm). Conversely, the spin time may be kept constant at from 30 seconds to 2 minutes and the butyl acetate concentration in the butyl acetate-silicone formulation may be in the upper half of its range (i.e., from 35 to 75 wt %), and then the spin speed may be set in the top half of its range (i.e., from 1900 to 3,000 rpm, that is relatively faster) for forming thinner films (i.e., films of thickness from 1 to 50 μm).

In spin-coating the butyl acetate-silicone formulation on a device wafer, a series of experiments may be conducted where the solids concentration in the butyl acetate-silicone formulation is varied. A spin curve plotting film thickness versus weight percent solids concentration at a particular spin speed may be produced, as for example in FIG. 4, and the spin curve may be used to adjust solids concentration for a particular spin speed protocol to give a desired film thickness. The following experiments illustrate the foregoing method. When the amount of the butyl acetate in the butyl acetate-silicone formulation is 50±2 wt %, spin-coating the formulation at 2,000 rpm may give a 4 μm thick coating or film. Alternatively, when the amount of the butyl acetate in the butyl acetate-silicone formulation is 16±2 wt %, spin-coating the formulation at 1,000 rpm may give a 40 μm thick coating or film.

Mixtures of the constituents (A), (B), and (C) may begin to cure at ambient temperature, e.g., 25°±3° C. To obtain a longer working time or “pot life” for the formulations, the activity of (C) the hydrosilylation catalyst under ambient conditions may optionally be retarded or suppressed by lowering the temperature of the formulations and/or by the addition of at least one constituent (E) a suitable inhibitor thereof. A platinum catalyst inhibitor retards curing of the formulations at ambient temperature, but does not prevent the formulations from curing at elevated temperatures (e.g., from 40° to 250° C.). Suitable platinum catalyst inhibitors include various “ene-yne” systems such as 3-methyl-3-penten-1-yne and 3,5-dimethyl-3-hexen-1-yne; acetylenic alcohols such as 3,5-dimethyl-1-hexyn-3-ol, 1-ethynyl-1-cyclohexanol, and 2-phenyl-3-butyn-2-ol; maleates and fumarates, such as the known dialkyl, dialkenyl, and dialkoxyalkyl fumarates and maleates; and cyclovinylsiloxanes. In some embodiments the inhibitor may comprise an acetylenic alcohol.

The concentration of optional constituent (E) the catalyst inhibitor in the butyl acetate-silicone formulation, and thus in the concentrated silicone formulation, is sufficient to retard curing of the formulation at ambient temperature without preventing or excessively prolonging cure at elevated temperatures. This concentration may vary depending on the particular inhibitor used, the nature and concentration of the hydrosilylation catalyst, and the nature of the constituent (B). Inhibitor concentrations as low as one mole of inhibitor per mole of platinum group metal will in some instances yield a satisfactory storage stability and cure rate. In other instances, inhibitor concentrations of up to 500 or more moles of inhibitor per mole of platinum group metal may be required. If desired, the optimum concentration for a particular inhibitor in a given formulation may be readily determined by routine experimentation.

Alternatively or additionally, the butyl acetate-silicone formulation may further comprise, alternatively may lack (i.e., be free of), one or more of constituent (F) an organic solvent that forms an azeotrope with butyl acetate, with the proviso that the azeotrope has a boiling point within plus-or-minus (±) 10° C., alternatively ±5° C., alternatively ±3° C. of the b.p. of butyl acetate. The azeotrope may be a binary azeotrope, alternatively a ternary azeotrope, alternatively a quaternary azeotrope. Examples of solvents that are known to form an azeotrope with butyl acetate and that may satisfy the proviso and thus be suitable as constituent (F) are: 1-butanol (azeotrope b.p. 117° C.); acetic acid; acetic acid/water; acetonitrile; acetonitrile/water; acetone; acetone/ethanol; ethanol; ethanol/water; ethyl acetate; ethyl acetate/water; ethyl acetate/benzene/water; methanol; methanol/water; 2-propanol; cyclohexane; hexane; chloroform; benzene; benzene/1-butanol; benzene/water; meta-xylene; and para-xylene. The b.p. of the foregoing azeotropes may be readily obtained from the literature. The azeotrope may have a b.p. that is lower, alternatively higher than the b.p. of butyl acetate. It may be advantageous to add a small amount of a constituent that forms a lower, alternatively higher boiling azeotrope with butyl acetate in order to lower, alternatively raise the temperature of the soft bake step, respectively.

The butyl acetate-silicone formulation and concentrated silicone formulation advantageously lack (i.e., are free of) any solvent, with the exception of the butyl acetate and, optionally, the aforementioned organic solvent that forms an azeotrope with butyl acetate. Examples of solvents excluded from the present formulations are saturated hydrocarbons having from 1 to 25 carbon atoms; aromatic hydrocarbons such as xylenes and mesitylene; mineral spirits; halohydrocarbons; esters; ketones; silicone fluids such as linear, branched, and cyclic polydimethylsiloxanes; and mixtures of such solvents, with the exception of the aforementioned organic solvent that forms an azeotrope with butyl acetate.

Alternatively or additionally, the butyl acetate-silicone formulation and concentrated silicone formulation advantageously may lack (i.e., be free of) silicon-containing monomers or oligomers, alternatively have from >0 to <1 wt % each of one or more of silicon-containing monomers or oligomers, based on total weight of the butyl acetate-silicone formulation or concentrated silicone formulation, respectively. The concentration of the silicon-containing monomers or oligomers in the butyl acetate-silicone formulation and concentrated silicone formulation may be controlled or decreased by fractional distillation, entrainment, stripping, or other removal thereof from the formulation. Alternatively or additionally, the concentration of the monomers or oligomers containing Si-alkoxy functional groups may be controlled by in situ condensation reaction thereof, such as in the soft bake or hard bake step of the photopatterning method.

The silicon-containing monomers include tetraalkylsilanes (e.g., tetramethylsilane, dim ethyldiethylsilane, or tetraethylsilane), trialkylalkoxysilanes (e.g., trimethylmethoxysilane, trimethylethoxysilane, or triethylmethoxysilane), dialkyldialkoxysilanes (e.g., dimethyldimethoxysilane, dimethyldiethoxysilane, or diethyldimethoxysilane), alkyltrialkoxysilanes (e.g., methyltrimethoxysilane, ethyltriethoxysilane, or methyltriethoxysilane), tetrakis(trialkylsilyloxy)silanes (e.g., tetrakis(trimethylsilyloxy)silane, tetrakis(triethylsilyloxy)silane, or tris(trimethylsilyloxy)-triethylsilyloxy-silane), dialkoxysilanes (e.g., dimethoxysilane (H₂Si(OCH₃)₂), diethoxysilane, or methoxyethoxysilane), trialkoxysilanes (e.g., trimethoxysilane (HSi(OCH₃)₃), triethoxysilane, or dimethoxyethoxysilane), and/or tetraalkoxysilanes (e.g., tetramethoxysilane, dimethoxydiethoxysilane, or tetraethoxysilane). The silicon-containing oligomers may be acyclic disilanes, trisilanes, or tetrasilanes having alkyl and/or alkoxy groups such as octamethyltrisiloxane (abbreviated L3), decamethyltetrasiloxane (abbreviated L4), or dodecamethylpentasiloxane (abbreviated L5). The silicon-containing oligomers may also be cyclic siloxanes (e.g., octamethyltetrasiloxane (abbreviated D4), decamethylpentasiloxane (abbreviated D5), and dodecamethylhexasiloxane (abbreviated D6)).

The butyl acetate-silicone formulation, concentrated silicone formulation, butyl acetate-free silicone formulation, and cured silicone products thereof independently advantageously may have 0 wt %, alternatively have from >0 to <0.75 wt %, alternatively have from >0 to <0.5 wt %, alternatively have from >0 to <0.3 wt %, alternatively have from >0 to <0.2 wt %, alternatively have from >0 to <0.1 wt %, alternatively have from >0 to <0.05 wt %, alternatively have from >0 to <0.02 wt % (e.g., <0.01 wt %) of any one of the foregoing examples of the silicon-containing monomers and independently have 0 wt %, alternatively have from >0 to <0.5 wt %, alternatively have from >0 to <0.3 wt %, alternatively have from >0 to <0.2 wt %, alternatively have from >0 to <0.1 wt %, alternatively have from >0 to <0.05 wt % of any one of the foregoing examples of the silicon-containing oligomers. For example, the butyl acetate-silicone formulation, concentrated silicone formulation, butyl acetate-free silicone formulation, and cured silicone products thereof independently may have from 0 to <0.5 wt % of any one of tetramethoxysilane, tetrakis(trimethylsilyloxy)silane, and dimethoxysilane and from 0 to <0.5 wt % of any one of L3, L4, L5, D4, D5 and D6. Alternatively, the butyl acetate-silicone formulation, concentrated silicone formulation, butyl acetate-free silicone formulation, and cured silicone products thereof independently may have from 0 to <0.05 wt % of any one of tetramethoxysilane, tetrakis(trimethylsilyloxy)silane, and dimethoxysilane and from 0 to <0.50 wt % total concentration of L3, D4 and D5; alternatively from 0 to <0.05 wt % of tetramethoxysilane and from 0 to <0.50 wt % total concentration of L3, D4 and D5; alternatively from 0 to <0.05 wt % of tetrakis(trimethylsilyloxy)silane and from 0 to <0.5 wt % total concentration of L3, D4 and D5; alternatively from 0 to <0.05 wt % of dimethoxysilane and from 0 to <0.50 wt % total concentration of D4 and D5. In some embodiments, the butyl acetate-silicone formulation, concentrated silicone formulation, butyl acetate-free silicone formulation, and cured silicone products thereof independently may lack (i.e., is free of (concentration=0.00 wt % of)) at least one of the tetrakis(trimethylsilyloxy)silane, L3, D4, and D5. Alternatively, the butyl acetate-silicone formulation, concentrated silicone formulation, butyl acetate-free silicone formulation, and cured silicone products thereof independently may lack (i.e., 0.00 wt % of) the tetrakis(trimethylsilyloxy)silane and have from 0 to <0.50 wt % total concentration of L3, D4 and D5. Alternatively, the butyl acetate-silicone formulation, concentrated silicone formulation, butyl acetate-free silicone formulation, and cured silicone products thereof independently may lack (i.e., 0.00 wt % of) each of the tetrakis(trimethylsilyloxy)silane, L3, D4 and D5. In any one of the foregoing embodiments, the material that lacks (i.e., is free of) at least one of the tetrakis(trimethylsilyloxy)silane, L3, D4, and D5 is the butyl acetate-free silicone formulation and the butyl acetate-free cured silicone product.

Optionally, the butyl acetate-silicone formulation and concentrated silicone formulation independently may further comprise one or more additional constituents other than constituents (A) to (D), the independently optional constituents (E) and (F), and the previously excluded solvents and excluded silicon-containing monomers and oligomers; with the proviso that the formulations and cured products lack (i.e., are free of) a thermally conductive filler. Such additional constituents may be added to the formulations provided they do not fatally affect the use of the formulations in or for preparing the cured silicone products, articles and semiconductor packages. Examples of suitable additional constituents are (G) adhesion promoters, (H) organic fillers, (I) photosensitizers, and (J) surfactants.

The thermally conductive filler that is excluded from the inventive formulations and cured products may be both thermally conductive and electrically conductive; alternatively thermally conductive and electrically insulating. The excluded thermally conductive filler may be any of the thermally conductive fillers described in U.S. Pat. No. 8,440,312 B2, column 8, line 32, to column 10, line 14; which description is hereby incorporated by reference herein. For example, the excluded thermally conductive filler may be selected from the group consisting of aluminum nitride, aluminum oxide, aluminum trihydrate, barium titanate, beryllium oxide, boron nitride, carbon fibers, diamond, graphite, magnesium hydroxide, magnesium oxide, metal particulate, onyx, silicon carbide, tungsten carbide, zinc oxide, and a combination thereof. The excluded thermally conductive filler may comprise a metallic filler, an inorganic filler, a meltable filler, or a combination thereof. Metallic fillers include particles of metals and particles of metals having layers on the surfaces of the particles. These layers may be, for example, metal nitride layers or metal oxide layers on the surfaces of the particles. Metallic fillers are exemplified by particles of metals selected from the group consisting of aluminum, copper, gold, nickel, silver, and combinations thereof. Metallic fillers are further exemplified by particles of the metals listed above having layers on their surfaces selected from the group consisting of aluminum nitride, aluminum oxide, copper oxide, nickel oxide, silver oxide, and combinations thereof.

The butyl acetate-silicone formulation and concentrated silicone formulation independently may be a one-part formulation comprising constituents (A) through (D) in a single part or, alternatively, a multi-part formulation comprising constituents (A) through (D) in two or more parts. In a multi-part formulation, constituents (A), (B), and (C) are typically not present in the same part unless constituent (E) an inhibitor is also present. For example, a multi-part silicone formulation may comprise a first part containing a portion of constituent (A), all of constituent (B), and a portion of constituent (D); and a second part containing the remaining portion of constituent (A), all of component (C), the remaining portion of constituent (D), and, if used, all of optional constituent (E).

The one-part butyl acetate-silicone formulation is typically prepared by combining constituents (A) through (D) and any optional constituents in the stated proportions at ambient temperature. Although the order of addition of the various constituents is not critical if the formulation is to be used immediately, constituent (C) the hydrosilylation catalyst is preferably added last at a temperature below about 30° C. to prevent premature curing of the formulation. The multi-part silicone formulation may be prepared by combining the particular components designated for each part.

The butyl acetate-silicone formulation is useful for making the concentrated silicone formulation. A method of making the concentrated silicone formulation comprises soft baking the butyl acetate-silicone formulation so as to remove a sufficient amount of butyl acetate therefrom so as to give the concentrated silicone formulation having at most the residual amount of butyl acetate. The invention, however, also includes other materials for making the concentrated silicone formulation, including directly mixing the constituents of the concentrated silicone formulation together with the butyl acetate remainder.

As described earlier, the use of the term “coating effective amount” does not limit the method of applying the formulation to a substrate to any particular application method (e.g., to only spin-coating) and does not limit the shape or form of applied formulation to only a coating or a film. The formulation may be applied on the substrate via various methods. For example, in certain embodiments, the step of applying the formulation on the substrate comprises a wet coating method. Specific examples of wet coating methods suitable for the method include curtain coating, dip coating, spin coating, flow coating, spray coating, roll coating, gravure coating, sputtering, slot coating (slot die coating), web coating, and combinations thereof. In spray coating, the butyl acetate-silicone formulation further comprises a co-solvent having a lower boiling point (e.g., from 50° to 110° C.) than that of butyl acetate and being capable of dissolving in the formulation so as to not phase separate therefrom. The co-solvent may be used in spray coating methods so that these aspects of the butyl acetate-silicone formulation are sprayed as a fine mist rather than as coarse droplets. The amount of co-solvent used may be from >0 volume percent (vol %) to 80 vol % based on total volume of butyl acetate and co-solvent. In some embodiments the co-solvent may be methyl ethyl ketone (MEK), hexamethyldisiloxane (HMDSO), or a mixture thereof. Alternatively, the co-solvent may be a solvent that forms an azeotrope with butyl acetate, alternatively a solvent that does not form an azeotrope with butyl acetate), with the proviso that the co-solvent is not acetone or isopropyl alcohol. Curtain coating, slot die coating, or web coating methods may be used in embodiments wherein two or more different formulations are applied simultaneously to form a multi-layer system comprising a substrate and first and second formulation layers, or form a multi-layer system comprising an initial layer (which would be cured to the substrate) and first and second formulation layers.

The method of making a concentrated silicone formulation comprises coating and/or soft baking (e.g., spin-coating and/or soft baking) the butyl acetate-silicone formulation so as to remove from 90 percent to less than 100 percent of the coating effective amount of (D) butyl acetate therefrom without curing same so as to give a concentrated silicone formulation consisting essentially of (A) an organopolysiloxane containing an average, per molecule, of at least two alkenyl groups; (B) an organosilicon compound containing an average, per molecule, of at least two silicon-bonded hydrogen atoms; a catalytic amount of (C) a hydrosilylation catalyst; and a residual amount of (D) butyl acetate. The phrase “consists essentially of” in this context means that the concentrated silicone formulation may not contain more than the residual amount of butyl acetate, and in some embodiments may not contain any solvent other than butyl acetate; and may not contain any silicon-containing monomers or oligomers and may not contain any thermally conductive filler; but otherwise may optionally contain any one or more optional constituents such as any one or more of the optional constituents (E) to (J). In some embodiments the method comprises spin-coating, but not soft baking; in other embodiments the method comprises soft-baking but not spin-coating; and in still other embodiments the method comprises spin coating and soft baking. In the latter embodiments, the soft baking step may be performed before, simultaneously with, or after the spin-coating step. Typically the spin-coating step is performed before the soft baking step. Removing from 90% to <100% of the coating effective amount of butyl acetate from the butyl acetate-silicone formulation means the residual amount of butyl acetate in the concentrated silicone formulation is from 10% to >0%, respectively of the coating effective amount thereof.

In some embodiments of the method of making a concentrated silicone formulation, the coating step comprises spin-coating. The spin-coating may be performed before the soft baking step as described earlier and may, depending on spin speed used, produce a film of an initial silicone formulation on a substrate, wherein the in initial silicone formulation has from 0 to less than 50 percent of the coating effective amount of (D) butyl acetate. If the spin speed is sufficiently high and/or the spin time period is sufficiently long, the initial silicone formulation may be the concentrated silicone formulation and contain no more than the residual amount of (D) butyl acetate. In some embodiments the spin-coating may remove a sufficient amount of (D) butyl acetate such that the soft baking step is not needed in any of the inventive methods described herein. Alternatively, and typically, the spin-coating may produce an initial film having a reduced amount of butyl acetate (e.g., if an open cup spin coater apparatus is used) and in need of additional removal of (D) butyl acetate such that the soft baking step may follow the spin-coating step to give the concentrated silicone formulation, or if desired, to give the butyl acetate-free curable silicone formulation, as the evaporating conditions may be. Alternatively, the butyl acetate-silicone formulation may be coated on a substrate without evaporating the butyl acetate during the coating (e.g., if a closed cup spin coater apparatus is used), and then the resulting “wet” film may be soft baked to give (a film of) the concentrated silicone formulation or the butyl acetate-free silicone formulation, as the evaporating conditions may be. In any of the foregoing embodiments that give a film of the butyl acetate-free silicone formulation on the front side of the substrate, the film/substrate system may be subjected to an edge bead removal step (e.g., using an open cup spin coater) comprising contacting the edge and backside of the substrate with a solvent so as to remove any excess butyl acetate-free silicone formulation material therefrom. The excess butyl acetate-free silicone formulation material may have gotten onto the backside and edge of the substrate during the spin-coating step. In some embodiments the edge bead removal step may also remove a narrow (e.g., 1 millimeter wide) perimeter of the film from the front side of the substrate so as to give an edge beaded film/substrate system lacking the butyl acetate-free silicone formulation material on the backside, edge, and outer perimeter of the front side of the substrate. Edge bead removal methods are generally well known in the art. The solvent for edge bead removal may be any suitable solvent, e.g., butyl acetate.

The concentrated silicone formulation consists essentially of constituents (A) to (C) and the residual amount of constituent (D) the butyl acetate. The transitional phrase “consists essentially of” in this context means that the concentrated silicone formulation may not contain more than the residual amount of butyl acetate, and in some embodiments may not contain any solvent other than butyl acetate and may not contain any silicon-containing monomers or oligomers, and lacks (i.e., is free of) a thermally conductive filler, but otherwise may optionally contain any one or more optional constituents such as any one or more of the optional constituents (E) to (J).

The residual amount of butyl acetate in the concentrated silicone formulation may depend on the coating effective amount of butyl acetate in the butyl acetate-silicone formulation. In some embodiments, the residual amount of butyl acetate in the concentrated silicone formulation is from 91% to 99.99%, alternatively from 92% to 99.9%, alternatively from 95% to 99.99%, alternatively from 98 to 99.99% of the coating effective amount of butyl acetate in the butyl acetate-silicone formulation.

The residual amount of butyl acetate in the concentrated silicone formulation may be a concentration that, upon curing the concentrated silicone formulation to give the cured silicone product, the cured silicone product retains at least some, alternatively all, of the residual amount of butyl acetate, which would make the cured silicone product less prone to premature drying than a comparative cured silicone product that is the same except contains a lower boiling point solvent (e.g., b.p. from 50° to 120° C.) instead of butyl acetate. Further, the cured silicone product is resistant to cracking. The residual amount of the butyl acetate in the concentrated silicone formulation may be expressed as a weight percent of the total weight of the concentrated silicone formulation. The residual amount of the butyl acetate in the concentrated silicone formulation may be from 0 to <5 wt %, alternatively from 0 to 4 wt %, alternatively from 0 to 3 wt %, alternatively from 0 to 2 wt %, alternatively from 0 to 1 wt %, alternatively from 0 to 0.5 wt %, alternatively from >0 to <5 wt %, alternatively from >0 to 4 wt %, alternatively from >0 to 3 wt %, alternatively from >0 to 2 wt %, alternatively from >0 to 1 wt %, alternatively from >0 to 0.5 wt %, all based on total weight of the concentrated silicone formulation. Alternatively, the residual amount of the butyl acetate in the concentrated silicone formulation may be from 0 to 500 parts per million (ppm), alternatively from 0 to 100 ppm, alternatively from 0 to 50 ppm, alternatively from 0 to 20 ppm, alternatively from 0 to 10 ppm, alternatively from 0 to 5 ppm; alternatively from >0 to 5 ppm, alternatively from >0 to 4 ppm, alternatively from >0 to 3 ppm, alternatively from >0 to 2 ppm, alternatively from >0 to 1 ppm, all based on total weight of the concentrated silicone formulation.

The method of making a cured silicone product comprises hydrosilylation curing the concentrated silicone formulation to give the cured silicone product. In some embodiments (C) the hydrosilylation catalyst is the photoactivatable hydrosilylation catalyst and the method comprises radiating the catalyst with light having a wavelength from 300 to 800 nm to give an irradiated silicone formulation, and heating the irradiated silicone formulation to give the cured silicone product. The light may be I-line radiation (365 nm) or broadband radiation (which contains I-line radiation).

The inventive embodiments further include the cured silicone product. In some such embodiments the cured silicone product further contains a residual amount of (D) butyl acetate. In other such embodiments, the cured silicone product lacks butyl acetate, i.e., is the butyl acetate-free cured silicone product.

The cured silicone product is made by the method of making same. The residual amount of the butyl acetate in the cured silicone product may be expressed as a weight percent of the total weight of the cured silicone product. The residual amount of the butyl acetate in the cured silicone product may be from 0 to <5 wt %, alternatively from 0 to 4 wt %, alternatively from 0 to 3 wt %, alternatively from 0 to 2 wt %, alternatively from 0 to 1 wt %, alternatively from 0 to 0.5 wt %, alternatively from >0 to <5 wt %, alternatively from >0 to 4 wt %, alternatively from >0 to 3 wt %, alternatively from >0 to 2 wt %, alternatively from >0 to 1 wt %, alternatively from >0 to 0.5 wt %, all based on total weight of the cured silicone product. As described above, the cured silicone product containing the residual amount of butyl acetate may be less prone to drying. Further, the cured silicone product is resistant to cracking.

Alternatively, the method of making a concentrated silicone formulation comprises soft baking the butyl acetate-silicone formulation so as to remove 100 percent of the coating effective amount of (D) butyl acetate therefrom without curing same so as to give a butyl acetate-free silicone formulation consisting essentially of (A) an organopolysiloxane containing an average, per molecule, of at least two alkenyl groups; (B) an organosilicon compound containing an average, per molecule, of at least two silicon-bonded hydrogen atoms; and a catalytic amount of (C) a hydrosilylation catalyst; but lacking (being free of) (D) butyl acetate. The phrase “consisting essentially of” in this context means lacking (i.e., being free of) (D) butyl acetate; and lacking any other organic solvent having a boiling point 120° C.; and lacking (i.e., being free of) a thermally conductive filler. This aspect may also be referred to herein as a method of making a butyl acetate free curable silicone formulation.

The step of removing some, but not all, of the butyl acetate may be accomplished by a step of coating (e.g., spin coating) the butyl acetate-silicone formulation on a substrate. Such a coating (e.g., spin-coating) step may naturally evaporate some, but not all, of the coating effective amount of butyl acetate from the spun-coated butyl acetate-silicone formulation to give a film of the concentrated silicone formulation on the substrate. The step of removing the remainder of the butyl acetate from the film of the concentrated silicone formulation may be accomplished by a step of soft baking the film of the concentrated silicone formulation on the substrate to give a film of the butyl acetate-free curable silicone formulation on the substrate.

Alternatively, the method of making a cured silicone product comprises removing all of the (D) butyl acetate from the butyl acetate-silicone formulation or concentrated silicone formulation without curing same to give a butyl acetate-free curable silicone formulation and hydrosilylation curing the butyl acetate-free silicone formulation to give a butyl acetate-free cured silicone product that lacks (i.e., is free of) butyl acetate. In some embodiments (C) the hydrosilylation catalyst is the photoactivatable hydrosilylation catalyst and the method comprises radiating the catalyst with light having a wavelength from 300 to 800 nm to give an irradiated silicone formulation, and heating the irradiated silicone formulation to give the butyl acetate-free cured silicone product

The method of forming the temporary-bonded substrate system comprises the aforementioned steps (a) to (d): (a) applying either one of the formulations to a surface of the carrier substrate to form a film of the formulation on the carrier substrate; (b) soft baking the film of step (a) so as to remove butyl acetate therefrom without curing the film to give a butyl acetate-free curable film/carrier substrate article; (c) in a bond chamber under vacuum, contacting the butyl acetate-free curable film of the article of step (b) to the release layer of a functional substrate/release layer article to give a contacted substrate system comprising sequentially a functional substrate, a release layer, a butyl acetate-free curable film, and a carrier substrate; and (d) in the bond chamber under vacuum exposing the contacted substrate system to an applied force of from greater than 1,000 Newtons (N) to 10,000 N and a temperature from 20 degrees Celsius (° C.) to 300° C. so as to partially cure the butyl acetate-free curable film to give a partially cured film in the contacted substrate system; and heating the contacted substrate system with the partially cured film at ambient pressure to give a temporary-bonded substrate system comprising sequentially the functional substrate, the release layer, an adhesive layer, and the carrier substrate. Step (a) may be performed before step (b), step (b) before step (c), and step (c) before or simultaneously with step (d).

In any inventive method herein, any contacting of articles together under vacuum in the bond chamber may be carried out by placing the articles in the bond chamber, evacuating the gaseous atmosphere from the bond chamber to give an evacuated bond chamber containing the articles, and then contacting under vacuum the articles together in the evacuated bond chamber to give a contacted substrate system. Any heating of the contacted substrate system with the partially cured film at ambient pressure may be done at an ambient pressure of from 90 to 110 kilopascals (kPa), such as 101 kPa. Any heat source used in the methods of making herein may be any means of increasing the temperature of an uncured or partially cured film such as a hotplate or oven. The oven may be a batch or continuous feed oven. In some embodiments the partially cured films are heated under vacuum in the bond chamber to give the fully cured films, although these alternative aspects of the inventive methods are less attractive from a cost/process throughput perspective than doing the heating of the partially cured films outside the bond chambers at ambient pressure to give the fully cured films. Contacted means indirectly, alternatively directly physically touching.

In any inventive method of forming a film of the cured silicone product herein, the method may further comprise repeating the steps used to form a first film of the cured silicone product to form a multilayer film of the cured silicone product. Each film layer of the cured silicone product in the multilayer film independently may be the same as, or different than, any other film layer therein in terms of composition of the cured silicone product, thickness of the film layer, structural features defined by the film layer (e.g., vias), or the like.

In some embodiments of the method of forming the temporary-bonded substrate system, the step (a) may further comprise exposing the film of the formulation on the carrier substrate article to ultraviolet radiation having a wavelength comprising I-line radiation so as to produce an exposed film on the carrier substrate. Typically, the radiation is either broadband ultraviolet light or only I-line (365 nm) UV light. The exposed film would thus be what is soft baked in step (b). The entire film may be exposed to the UV radiation. This extent of exposure may be referred to herein as “flood exposure.” (Flood exposure is in contrast to a photopatterning exposure step wherein a photom ask is used such that only portions of the film would be exposed to the UV radiation and other portions of the film that would be masked or not exposed thereto.) The UV exposure step would allow lower cure temperatures to be used in step (d). Lower cure temperatures in step (d) may be helpful when the carrier substrate is composed of a material such as an epoxy, which may warp at very high cure temperatures. The film may be exposed to the UV radiation directly or indirectly. The direct exposure may be performed when the carrier substrate absorbs and blocks transmittance of UV radiation, such as when the carrier substrate is a silicon wafer. The indirect exposure may be performed by irradiating the surface of the carrier substrate that is opposite the surface of the carrier substrate that is in contact with the film. The indirect exposure may be done when the carrier substrate is transparent to UV radiation (e.g., when the carrier substrate is a silicate glass). Alternatively, when the carrier substrate is transparent to UV radiation, the exposing step may be performed after step (d), wherein the adhesive layer of the temporary-bonded substrate system is irradiated with UV radiation indirectly via the transparent carrier substrate.

Alternatively or additionally in some embodiments of the method of forming the temporary-bonded substrate system, the method may further comprise a step of forming the functional substrate/release layer article prior to step (c) by soft baking a film of a solvent-containing release layer composition on the functional substrate so as to remove the solvent therefrom to give the functional substrate/release layer article. The functional substrate may be a device wafer such as a semiconductor device wafer; alternatively steps (c) and (d) are performed simultaneously; alternatively the functional substrate is a semiconductor device wafer and steps (c) and (d) are performed simultaneously. Steps (c) and (d) may be performed simultaneously. Alternatively, steps (c) and (d) are performed sequentially by placing the butyl acetate-free curable film/carrier substrate article of step (b) and the functional substrate/release layer article of step (c) in the bond chamber used in step (d), evacuating the gaseous atmosphere from the bond chamber, and then contacting under vacuum the butyl acetate-free curable film of the article of step (b) to the release layer of the article of step (c), and then applying a force and optionally heating the articles in the bond chamber to the applied force of from greater than 1,000 Newtons (N) to 10,000 N and the temperature from 20° C. to 300° C., so as to partially cure the butyl acetate-free curable film to give a partially cured film in the contacted substrate system; and heating the contacted substrate system with the partially cured film at ambient pressure to give the temporary-bonded substrate system comprising sequentially the functional substrate, the release layer, an adhesive layer, and the carrier substrate.

The temporary-bonded substrate system may comprise a temporary-bonded wafer system wherein the carrier substrate is a carrier wafer and the functional substrate is a semiconductor device wafer.

The method of debonding comprises subjecting the temporary-bonded substrate system to a debonding condition comprising applying a mechanical force so as to separate the functional substrate from the carrier substrate or vice versa to give an intact functional substrate. The method may further comprise a preliminary step of processing the temporary-bonded substrate system to give a processed temporary-bonded substrate system, which is then subjected to the debonding step. The processing step may comprise performing any one or more of the following functions on the functional substrate of the temporary-bonded substrate system: redistribution dielectric layers (RDL), photopatterning, 3-dimensional integrating or stacking, fabricating TSVs (through-silicon vias), microbumping, planarizing, trimming, or thinning.

In the method of forming a permanent-bonded substrate system sequentially consisting essentially of a functional substrate/adhesive layer/carrier substrate, the method comprises steps (a) to (d): (a) applying either one of the butyl acetate-silicone formulation or the concentrated silicone formulation to a surface of the carrier substrate or the functional substrate to form an article of a film of the formulation on the carrier substrate or the functional substrate; (b) soft baking the film of the article of step (a) so as to remove butyl acetate therefrom without curing the film to give an article of a butyl acetate-free curable film on the carrier substrate or the functional substrate; (c) in a bond chamber under vacuum, contacting the butyl acetate-free curable film of step (b) to the other of the carrier substrate or functional substrate to give a contacted substrate system sequentially consisting essentially of a functional substrate, a butyl acetate-free curable film, and a carrier substrate; and (d) in the bond chamber under vacuum exposing the contacted substrate system to an applied force of from greater than 1,000 Newtons (N) to 10,000 N and a temperature from 20 degrees Celsius (° C.) to 300° C. so as to partially cure the butyl acetate-free curable film to give a partially cured film in the contacted substrate system; and heating the contacted substrate system with the partially cured film at ambient pressure to give a permanent-bonded substrate system consisting essentially of sequentially the functional substrate, an adhesive layer, and the carrier substrate. The permanent-bonded substrate system sequentially consists essentially of a functional substrate/adhesive layer/carrier substrate. The phrase “consists essentially of” in this context means the permanent-bonded substrate system lacks (i.e., is free of) a release layer between the functional substrate and carrier substrate. Step (a) may be performed before step (b), step (b) before step (c), and step (c) before or simultaneously with step (d).

In some embodiments of the method of forming the permanent-bonded substrate system, the step (a) may further comprise exposing the film of the formulation on the carrier substrate article to ultraviolet radiation having a wavelength comprising I-line radiation (e.g., 365 nm so as to produce an exposed film on the carrier substrate. Typically, the radiation is either broadband ultraviolet light or I-line only (365 nm) UV light. The exposed film would thus be what is soft baked in step (b). The entire film may be exposed to the UV radiation as in a flood exposure. As before, the UV exposure step would allow lower cure temperatures to be used in step (d). Lower cure temperatures in step (d) may be helpful when the carrier substrate is composed of a material such as an epoxy, which may warp at very high cure temperatures. The film may be exposed to the UV radiation directly or indirectly. The direct exposure may be performed when the carrier substrate absorbs and blocks transmittance of UV radiation, such as when the carrier substrate is a silicon wafer. The indirect exposure may be performed by irradiating the surface of the carrier substrate that is opposite the surface of the carrier substrate that is in contact with the film. The indirect exposure may be done when the carrier substrate is transparent to UV radiation (e.g., when the carrier substrate is a silicate glass). Alternatively, when the carrier substrate is transparent to UV radiation, the exposing step may be performed after step (d), wherein the adhesive layer of the permanent-bonded substrate system is irradiated with UV radiation indirectly via the transparent carrier substrate.

Alternatively or additionally, in the method of forming the permanent-bonded substrate system, the step (a) may further comprise applying independently either one of the butyl acetate-silicone formulation or the concentrated silicone formulation to a surface of the other of the carrier substrate or the functional substrate to form another article of a film of the formulation on the other of the carrier substrate or the functional substrate; and step (b) may further comprise soft baking the film of the other article so as to remove butyl acetate therefrom without curing the film to give another article of a butyl acetate-free curable film on the other of the carrier substrate and the functional substrate; and step (c) may further comprise contacting the butyl acetate-free curable films of the articles together to give a contacted substrate system sequentially consisting essentially of a functional substrate, a butyl acetate-free curable film, another butyl acetate-free film, and a carrier substrate; and step (d) then gives the permanent-bonded substrate system consisting essentially of sequentially the functional substrate, an adhesive layer, and the carrier substrate. The functional substrate may be a semiconductor device wafer; alternatively steps (c) and (d) are performed simultaneously; alternatively the functional substrate is a semiconductor device wafer and steps (c) and (d) are performed simultaneously. Steps (c) and (d) may be performed simultaneously. Alternatively, steps (c) and (d) are performed sequentially by placing the butyl acetate-free curable film/carrier substrate article of step (b) and the other of the carrier substrate or functional substrate of step (c) in the bond chamber used in step (d), evacuating the gaseous atmosphere from the bond chamber, and then contacting under vacuum the butyl acetate-free curable film of the article of step (b) to the other of the carrier substrate or functional substrate of step (c), and optionally heating the article and the other of the carrier substrate or functional substrate in the bond chamber to the applied force of from greater than 1,000 Newtons (N) to 10,000 N and the temperature from 20° C. to 300° C., so as to partially cure the butyl acetate-free curable film to give a partially cured film in the contacted substrate system; and heating the contacted substrate system with the partially cured film at ambient pressure to give the permanent-bonded substrate system sequentially consisting essentially of a functional substrate/adhesive layer/carrier substrate. The phrase “consists essentially of” in this context means the permanent-bonded substrate system lacks (i.e., is free of) a release layer between the functional substrate and carrier substrate.

The permanent-bonded substrate system may comprise a temporary-bonded wafer system wherein the carrier substrate is a carrier wafer and the functional substrate is a semiconductor device wafer.

In some embodiments the article comprises the substrate and the butyl acetate-silicone formulation. In other embodiments the article comprises the substrate and the concentrated silicone formulation. In still other embodiments the article comprises the cured silicone product and a substrate. The formulation or product is disposed on the respective substrate. The article may comprise the substrate and the butyl acetate-silicone formulation, alternatively the substrate and the concentrated silicone formulation, alternatively the substrate and the cured silicone product, alternatively the substrate and at least two of the formulations and product. The cured silicone product may be made by the method of making same.

Alternatively, the article comprises the substrate and the butyl acetate-free silicone formulation, alternatively the substrate and the butyl acetate-free cured silicone product.

The substrate used in the article may be rigid or flexible. Examples of suitable rigid substrates include inorganic materials, such as glass plates; glass plates comprising an inorganic layer; ceramics; and silicon-containing wafers, such as silicon wafers, silicon wafers having a layer of silicon carbide disposed thereon, silicon wafers having a layer of silicon oxide disposed thereon, silicon wafers having a layer of silicon nitride disposed thereon, silicon wafers having a layer of silicon carbonitride disposed thereon, silicon wafers having a layer of silicon oxycarbonitride disposed thereon, and the like. The term “silicon wafer” used by itself (i.e., without specifying a layer of a different material thereon) may consist essentially of monocrystalline silicon or polycrystalline silicon. The phrase “consist essentially of” in this context means the silicon wafer does not contain a layer of silicon carbide, silicon nitride, silicon oxide, silicon carbonitride, silicon oxycarbonitride, sapphire, gallium nitride, or gallium arsenide. Additional examples of suitable substrate materials are sapphire, silicon wafers having a layer of gallium nitride disposed thereon, and gallium arsenide wafers. In some embodiments the substrate comprises a silicon wafer or a silicon wafer having disposed thereon a layer of silicon carbide, silicon nitride, silicon oxide, silicon carbonitride, silicon oxycarbonitride, sapphire, gallium nitride, or gallium arsenide. In some embodiments the substrate comprises a silicon wafer, alternatively a silicon wafer having disposed thereon a layer of silicon carbide, alternatively a silicon wafer having disposed thereon a layer of silicon nitride. The disposed layer may be applied, deposited or built on the silicon wafer using any suitable method such as chemical vapor deposition, which may be plasma enhanced.

In other embodiments, it may be desirable for the substrate to be flexible. In these embodiments, specific examples of flexible substrates include those comprising various silicone or organic polymers. From the view point of transparency, refractive index, heat resistance and durability, specific examples of flexible substrates include those comprising polyolefins (polyethylene, polypropylene, etc.), polyesters (poly(ethylene terephthalate), poly(ethylene naphthalate), etc.), polyamides (nylon 6, nylon 6,6, etc.), polystyrene, poly(vinyl chloride), polyimides, polycarbonates, polynorbornenes, polyurethanes, poly(vinyl alcohol), poly(ethylene vinyl alcohol), polyacrylics, celluloses (triacetylcellulose, diacetylcellulose, cellophane, etc.), or interpolymers (e.g. copolymers) of such organic polymers. Typically, the flexible substrate is made of a material with sufficient heat resistance to survive a step of curing at an elevated temperature of from 170° to 270° C. (e.g., 180° to 250° C., e.g., about 210° C. Alternatively, from the view point of transparency, refractive index, heat resistance and durability, specific examples of flexible substrates include those comprising polyorganosiloxane formulations such as silsesquioxane-containing polyorganosiloxane formulations. As understood in the art, the organic polymers and silicone polymers recited above may be rigid or flexible. Further, the substrate may be reinforced, e.g. with fillers and/or fibers. The substrate may have a coating thereon, as described in greater detail below. The substrate may be separated from the article to give another invention article comprising the cured silicone layer and lacking the substrate, if desired, or the substrate may be an integral portion of the article.

The optical article comprises an element for transmitting light, the element comprising the cured silicone product. The cured silicone product of the optical article may be an optical passivation layer or a deformable membrane for use in a microelectromechanical system (MEMS). Alternatively, the optical article comprises an element for transmitting light, the element comprising the butyl acetate-free cured silicone product. The deformable membrane may be used to manufacture and used in the devices illustrated in any one of U.S. Pat. No. 8,072,689 B2; U.S. Pat. No. 8,363,330 B2; and U.S. Pat. No. 8,542,445 B2.

The optical device with a deformable membrane, the device comprising: (a) a deformable membrane having front and rear faces and a peripheral area (i.e., an anchoring area or a peripheral anchoring zone) which is anchored in a sealed manner on a support helping to contain a constant volume of liquid in contact with the rear face of the membrane, said peripheral area is an anchoring area that is a sole area of the membrane that is anchored on the support; and a substantially central area, configured to be deformed reversibly from a rest position; and (b) an actuation device (i.e., an actuation mechanism) configured for displacing the liquid in the central area, stressing the membrane in at least one area situated strictly between the central area and the anchoring area. The deformable membrane may have an intermediate zone or area between the central zone and the peripheral area. The deformable membrane is the cured silicone product. The optical device may comprise a MEMS. Alternatively, the deformable membrane is the butyl acetate-free cured silicone product.

The actuation device of the optical device may comprise plural micro-beam thermal or piezoelectric actuators, distributed at a periphery of the membrane, the micro-beam thermal or piezoelectric actuators including at least one part joined to the support that is fixed on an actuation and at least one moving part coming into contact, on an actuation, with the membrane in an area situated between the central area and the anchoring area. Examples of the micro-beam thermal or piezoelectric actuators are well known and may be found in U.S. Pat. No. 8,072,689 B2 to Bolis et al. Alternatively, the actuation device may be an electrostatic device having one or more movable parts, each movable part being formed from a leg terminating on one side in a foot mechanically fastened to a film-fastening region located in the intermediate zone and terminating on the other side in a free end, wherein the legs incorporate a movable electrode, the free end having to be attracted by a fixed electrode of the actuation device, the free end of the leg being placed facing the free end of the movable electrode so as to deform, upon activation of the actuation device, at least the central zone of the membrane. Examples of the electrostatic device having one or more movable parts are well known and are found in U.S. Pat. No. 8,363,330 B2 to Bolis et al. Alternatively, the actuation device may be electrostatic and comprise at least one pair of opposing electrodes, at least one of the electrodes of the pair being at a level of the rear face of the membrane or buried in the membrane, the other electrode of the pair being at a level of the support, the electrodes being separated by a dielectric material, the dielectric material being formed at least by the liquid. Examples of the electrostatic actuation device are well known and may be found in U.S. Pat. No. 8,542,445 B2 to Bolis et al.

The method of preparing a silicone layer of a semiconductor package comprising a semiconductor device wafer having an active surface comprising a plurality of surface structures; and a cured silicone layer covering the active surface of the wafer except the surface structures, the method comprising the steps of: (i) applying the butyl acetate-silicone formulation to the active surface of the semiconductor device wafer to form a coating thereon, wherein the active surface comprises a plurality of surface structures; (ii) removing from 90 percent to less than 100 percent of the coating effective amount of (D) butyl acetate from the coating so as to give a film of a formulation consisting essentially of (A) an organopolysiloxane containing an average, per molecule, of at least two alkenyl groups; (B) an organosilicon compound containing an average, per molecule, of at least two silicon-bonded hydrogen atoms in a concentration sufficient to cure the formulation; a catalytic amount of (C) a hydrosilylation catalyst; and a residual amount of (D) butyl acetate; (iii) exposing a portion of the film to radiation having a wavelength comprising I-line radiation without exposing another portion of the film to the radiation so as to produce a partially exposed film having non-exposed regions covering at least a portion of each bond pad and exposed regions covering the remainder of the active surface; (iv) heating the partially exposed film for an amount of time such that the exposed regions are substantially insoluble in a developing solvent and the non-exposed regions are soluble in the developing solvent; (v) removing the non-exposed regions of the heated film with the developing solvent to form a patterned film; and (vi) heating the patterned film for an amount of time sufficient to form the cured silicone layer.

Typically in step (iii), the radiation is either broadband ultraviolet light or I-line (365 nm) UV light. The exposing step may employ a photomask that may independently have defined open portions and an array of spaced-apart mask portions. The photomask may define the open portions to allow the radiation to pass by or through the photomask. The masked portions are for blocking the radiation, thereby creating the non-exposed regions and open portions. Each mask portion independently may be any shape or dimension such as circular, ovoid, square, rectangular, trapezoidal, straight line, curved line, or a combination of any two or more thereof. Each open portion and mask portion independently may have any suitable dimension for forming a photopattern having desired feature shapes and sizes.

In some aspects, the developing solvent may be butyl acetate. The use of a developing solvent that is the same as the coating solvent is advantageously simpler than a comparative method using mesitylene as a coating solvent and a different solvent (e.g., 2-propanol) as a developing solvent. Mesitylene does not work satisfactorily as a developing solvent because it is difficult to remove afterwards due to its high boiling point; because it may also dissolve unexposed silicone material, which is undesirable; and/or because droplets of mesitylene may run out (i.e., reach the edge of the substrate) and evaporate, thereby undesirably leaving behind after a hard bake (final cure) step a residue of silicone material. The cured silicone layer is an aspect of the cured silicone product. Alternatively, the cured silicone layer is an aspect of the butyl acetate-free cured silicone product. The steps of the method may be carried out as generally described in U.S. Pat. No. 6,617,674 B2 to Becker et al. except the silicone composition of the applying step of Becker et al. is replaced by the present butyl acetate-silicone formulation. In some embodiments the constituents (A) and (B) are proportioned in the butyl acetate-silicone formulation in such a way so as to configure the formulation with a SiH-to-alkenyl ratio, and the SiH-to-alkenyl ratio is from 0.65 to 1.05. The surface structures may comprise bond pads, test pads, dies separated by scribe lines, or a combination of any two or more surface structures thereof. As described earlier, in some embodiments the device wafer may comprise a silicon wafer having a silicon nitride layer disposed thereon, a silicon wafer having a silicon oxide layer disposed thereon, or a silicon wafer having both silicon nitride and silicon oxide layers disposed thereon. When the device wafer comprises a silicon wafer having a primary passivation stack comprising a silicon nitride layer and/or a silicon oxide layer disposed thereon, the cured silicone layer may comprise a hard mask that is substantially not removed during etching of the silicon oxide or silicon nitride layer(s) to reveal bond pads. There may be some loss of the cured silicone layer during the etching, but beneficially only about 1 μm thickness of the cured silicone layer is lost when etching a typical 1 μm thick primary passivation stack.

In some embodiments the method of preparing a silicone layer of a semiconductor package further comprises removing all of the cured silicone from the semiconductor package to give a semiconductor package that is free of the cured silicone layer.

In any method or system described herein, in some embodiments the carrier substrate may not be made of a semiconducting material. There is nothing, however, about “carrier” that precludes the carrier substrate from also being a functional substrate. In other embodiments the functional substrate may be a first functional substrate and the carrier substrate may be a second functional substrate and the temporarily- and permanent-bonding methods may comprise temporary-bonding or permanent-bonding two functional substrates together to give a system comprising first functional substrate/adhesive layer/second functional substrate.

The semiconductor package comprising a semiconductor device wafer having an active surface comprising a plurality of surface structures; and a cured silicone layer covering the active surface of the wafer except the surface structures, wherein the silicone layer is prepared by the method of preparing a silicone layer of a semiconductor package. The semiconductor package may be as generally described in U.S. Pat. No. 6,617,674 B2 to Becker et al. except the cured silicone layer of Becker et al. is replaced by the cured silicone product. Alternatively, the cured silicone layer is replaced by the butyl acetate-free cured silicone product. The surface structures may comprise bond pads, test pads, dies separated by scribe lines, or a combination of any two or more surface structures thereof. In some embodiments the semiconductor package is free of the cured silicone layer.

The electronic article comprises a dielectric layer disposed on a silicon nitride layer, the dielectric layer being made of the cured silicone product made by the method of making same. The dielectric layer may be any suitable thickness, e.g., from 5 to 100 μm, alternatively from 7 to 70 μm, alternatively from 10 to 50 μm. The dielectric layer at a given thickness may be characterized by its dielectric strength. For example, when the dielectric layer is 40 micrometers thick, the dielectric layer is characterized by a dielectric strength greater than 1.5×10⁶ Volts per centimeter (V/cm). The dielectric strength of the dielectric layer of the cured silicone product that has been prepared from the butyl acetate-silicone formulation according to an inventive method may be at least 2, alternatively at least 3, alternatively at least 4, alternatively at least 5 times greater than the dielectric strength of a comparative dielectric layer of a comparative cured silicone product that has been prepared from a silicone formulation that is identical to the butyl acetate-silicone formulation except wherein the coating effective amount of the butyl acetate has been replaced by an equivalent amount (weight) of an aromatic hydrocarbon such as mesitylene and/or xylenes.

The description of this invention uses certain terms and expressions. For convenience some of them are defined herebelow.

As used herein, “may” confers a choice, not an imperative. “Optionally” means is absent, alternatively is present. “Contacting” means bringing into physical contact. “Operative contact” comprises functionally effective touching, e.g., as for modifying, coating, adhering, sealing, or filling. The operative contact may be direct physical touching, alternatively indirect touching. All U.S. patent application publications and patents referenced hereinbelow, or a portion thereof if only the portion is referenced, are hereby incorporated herein by reference to the extent that incorporated subject matter does not conflict with the present description, which would control in any such conflict. All % are by weight unless otherwise noted. All “wt %” (weight percent) are, unless otherwise noted, based on total weight of all ingredients used to make the composition or formulation, which adds up to 100 wt %. Any Markush group comprising a genus and subgenus therein includes the subgenus in the genus, e.g., in “R is hydrocarbyl or alkenyl,” R may be alkenyl, alternatively R may be hydrocarbyl, which includes, among other subgenuses, alkenyl. The term “silicone” includes linear, branched, or a mixture of linear and branched polyorganosiloxane macromolecules.

The following materials and methods may be used in some embodiments.

Cyclic Siloxanes Detection Method: detect presence or absence of cyclic siloxanes by gas chromatography.

Shelf Life Stability Test Method: Measure weight average molecular weight, abbreviated as M_{W}^{FP}, of a test sample of a freshly-prepared vehicle-silicone formulation. Examples of such formulations are an inventive butyl acetate-silicone formulation or a non-inventive xylenes-silicone formulation. Allow the test sample formulation to stand at room temperature (23°±1° C.) for 28 days to give an aged sample formulation. Measure weight average molecular weight, abbreviated as M_{W}^{AG}, of the aged sample formulation, Calculate shelf life stability as the percent change in M_{W} after aging: % change in M_{W}=100*(M_{W}^{AG}−M_{W}^{FP})/M_{W}^{FP}.

Weight average molecular weight (M_{W}) Measurement Method: determine weight average molecular weight using gel permeation chromatography (GPC) relative to a polystyrene standards calibration curve.

Linear 1: a SiH-functional linear silicone of formula: D^{Me,H}_{0.085±0.005}D_{0.90±0.05}M_{0.015±0.005}.

Resin 1: a vinyl-functional MQ resin of the following formula: M^{Vi}_{0.055±0.005}Q_{0.45±0.05}T^{OH}_{0.065±0.005}M_{0.40±0.05}.

Masterbatch 1: a mixture containing 88 wt % of Resin 1 and 12 wt % of Linear 1.

The following examples are intended to illustrate the invention and are not to be viewed in any way as limiting to the scope of the invention. Parts are parts by weight based on total weight unless otherwise indicated.

### EXAMPLES

### Example 1: Butyl Acetate-Silicone Formulation (1)

To mix together 54±1 parts of a vinyl-functional MQ resin of the following formula: M^{Vi}_{0.055±0.005}Q_{0.45±0.05}T^{OH}_{0.065±0.005}M_{0.40±0.05}, 30±1 parts of a SiH-functional linear silicone of formula: D^{Me,H}_{0.085±0.005}D_{0.90±0.05}M_{0.015±0.005}, 16±1 parts butyl acetate, and 0.002 parts of a platinum hydrosilylation catalyst to give butyl acetate-silicone formulation (1). Butyl acetate-silicone formulation (1) is useful for forming a film thereof having a thickness from 30 to 100 μm (e.g., 40 μm).

### Example 2: Butyl Acetate-Silicone Formulation (2)

To mix together 53±1 parts of a vinyl-functional MQ resin of the following formula: M^{Vi}_{0.055}±_{0.005}Q_{0.45±0.05}T^{OH}_{0.065±0.005}M_{0.40±0.05}, 31±1 parts of a SiH-functional linear silicone of formula: D^{Me,H}_{0.085±0.005}D_{0.90±0.05}M_{0.015±0.005}, 16±1 parts butyl acetate, and 0.002 parts of a platinum hydrosilylation catalyst to give butyl acetate-silicone formulation (2). Butyl acetate-silicone formulation (2) is useful for forming a film thereof having a thickness from 30 to 100 μm (e.g., 40 μm).

### Example 3: Butyl Acetate-Silicone Formulation (3)

To mix together 55±1 parts of a vinyl-functional MQ resin of the following formula: M^{Vi}_{0.055±0.005}Q_{0.45±0.05}T^{OH}_{0.065±0.005}M_{0.40±0.05}, 29±1 parts of a SiH-functional linear silicone of formula: D^{Me,H}_{0.085±0.005}D_{0.90±0.05}M_{0.015±0.005}, 16±1 parts butyl acetate, and 0.002 parts of a platinum hydrosilylation catalyst to give butyl acetate-silicone formulation (3). Butyl acetate-silicone formulation (3) is useful for forming a film thereof having a thickness from 30 to 50 μm (e.g., 40 μm).

### Example 4: Butyl Acetate-Silicone Formulation (4)

To mix together 31±1 parts of a vinyl-functional MQ resin of the following formula: M^{Vi}_{0.055±0.005}Q_{0.45±0.05}T^{OH}_{0.065±0.005}M_{0.40±0.05}, 19±1 parts of a SiH-functional linear silicone of formula: D^{Me,H}_{0.085±0.005}D_{0.90±0.05}M_{0.015±0.005}, 50±3 parts butyl acetate, and 0.002 parts of a platinum hydrosilylation catalyst to give butyl acetate-silicone formulation (4). Butyl acetate-silicone formulation (4) is useful for forming a film thereof having a thickness from 3 to 10 μm (e.g., 4 μm).

### Example 5: Butyl Acetate-Silicone Formulation (5)

To mix together 32±1 parts of a vinyl-functional MQ resin of the following formula: M^{Vi}_{0.055±0.005}Q_{0.45±0.05}T^{OH}_{0.065±0.005}M_{0.40±0.05}, 18±1 parts of a SiH-functional linear silicone of formula: D^{Me,H}_{0.085±0.005}D_{0.90±0.05}M_{0.015±0.005}, 50±3 parts butyl acetate, and 0.002 parts of a platinum hydrosilylation catalyst to give butyl acetate-silicone formulation (5). Butyl acetate-silicone formulation (5) is useful for forming a film thereof having a thickness from 3 to 10 μm (e.g., 4 μm).

### Example 6: Butyl Acetate-Silicone Formulation (6)

To mix together 33±1 parts of a vinyl-functional MQ resin of the following formula: M^{Vi}_{0.055±0.005}Q_{0.45±0.05}T^{OH}_{0.065±0.005}M_{0.40±0.05}, 17±1 parts of a SiH-functional linear silicone of formula: D^{Me,H}_{0.085±0.005}D_{0.90±0.05}M_{0.015±0.005}, 50±3 parts butyl acetate, and 0.002 parts of a platinum hydrosilylation catalyst to give butyl acetate-silicone formulation (6). Butyl acetate-silicone formulation (6) is useful for forming a film thereof having a thickness from 3 to 10 μm (e.g., 4 μm).

### Examples 7A to 7H: Butyl Acetate-Silicone Formulations (7A) to (7H)

Separately mix together 100 parts of the Masterbatch 1; either 51±1, 47±1, 43±1, 40±1, 37±1, 34±1, 32±1, or 28±1 parts of additional Linear 1; 16±1 parts butyl acetate; and 0.002 parts of a platinum hydrosilylation catalyst to give butyl acetate-silicone formulation (7A), (7B), (7C), (7D), (7E), (7F), (7G), or (7H), respectively. Butyl acetate-silicone formulations (7A) to (7H) are useful for forming films thereof having a thickness from 30 to 100 μm (e.g., 40 μm). The constituents and SiH/Vi ratio of these butyl acetate-silicone formulations are listed in Table 1A. For clarity, the constituents of these butyl acetate-silicone formulations are also listed in an alternative, but equivalent, format in Table 1B.

TABLE 1A
constituents and SiH/Vi ratio of these butyl acetate-silicone
formulations (7A) to (7H).

| Constituent | (7A) | (7B) | (7C) | (7D) | (7E) | (7F) | (7G) | (7H) |
|---|---|---|---|---|---|---|---|---|
| Masterbatch 1 | 100 | 100 | 100 | 100 | 100 | 100 | 100 | 100 |
| (parts) | | | | | | | | |
| Additional | 51 ± 1 | 47 ± 1 | 43 ± 1 | 40 ± 1 | 37 ± 1 | 34 ± 1 | 32 ± 1 | 28 ± 1 |
| Linear 1 (parts) | | | | | | | | |
| Butyl acetate | 16 | 16 | 16 | 16 | 16 | 16 | 16 | 16 |
| (parts) | | | | | | | | |
| Pt Catalyst | 0.002 | 0.002 | 0.002 | 0.002 | 0.002 | 0.002 | 0.002 | 0.002 |
| (part) | | | | | | | | |
| SiH/Vi Ratio | 1.1 | N/D | 1.0 | N/D | 0.9 | N/D | 0.8 | 0.7 |
| (1H-NMR) | | | | | | | | |

N/D not determined.

TABLE 1B
constituents of these butyl acetate-silicone formulations (7A)
to (7H) listed in an alternative, but equivalent, format.

| Constituent | (7A) | (7B) | (7C) | (7D) | (7E) | (7F) | (7G) | (7H) |
|---|---|---|---|---|---|---|---|---|
| Resin 1 (parts)* | 49.0 | 50.3 | 51.7 | 52.8 | 54.0 | 55.2 | 56.0 | 57.8 |
| Total Linear 1 | 35.0 | 33.7 | 32.3 | 31.2 | 30.0 | 28.8 | 28.0 | 26.3 |
| (parts)** | | | | | | | | |
| Butyl acetate | 16 | 16 | 16 | 16 | 16 | 16 | 16 | 16 |
| (parts) | | | | | | | | |
| Pt Catalyst | 0.002 | 0.002 | 0.002 | 0.002 | 0.002 | 0.002 | 0.002 | 0.002 |
| (part) | | | | | | | | |

*from Masterbatch 1;
**from Masterbatch 1 and Additional Linear 1.

The butyl acetate-silicone formulations of (7A) to (7H) are converted to 40 μm thick films thereof of Examples (7A) to (7H), respectively, following the spin-coating, butyl acetate removal, and photopatterning procedures described for FIG. 1. The films of the formulations are converted to films of their corresponding concentrated silicone formulations of Examples (7A) to (7H), respectively. The concentrated silicone formulations are converted to their corresponding photopatterned cured silicone film/wafer laminates (PCS film/wafer) of Examples (7A) to (7H), respectively, using the 40 μm dot patterns on the mask. The film retentions, open or closed via status, via width (bottom, proximal to surface of wafer), and via depth are shown in Table 2.

TABLE 2
photopatterned cured silicone film/wafer laminates of
Examples (7A) to (7H).

| PCS film/wafer | (7A) | (7B) | (7C) | (7D) | (7E) | (7F) | (7G) | (7H) |
|---|---|---|---|---|---|---|---|---|
| Film Retention | 85 | 85 | N/D | 80 | 80 | 82 | 81 | 73 |
| (%) | | | | | | | | |
| Open Via | No | No | Yes | Yes | Yes | Yes | Yes | Yes |
| of ≧30 μm? | | | | | | | | |
| Via width (μm) | 15.05 | 12.71 | 22.0 | 20.74 | 27.46 | 24.23 | 23.41 | 31.42 |
| (bottom) | | | | | | | | |
| SiH/Vi (1H- | 1.1 | N/D | 1.0 | N/D | 0.9 | N/D | 0.8 | 0.7 |
| NMR) | | | | | | | | |
| Via depth (μm) | 31.2 | 34.4 | N/D | 34.4 | 35.3 | 37.1 | 39.9 | 37.5 |

As may be seen with the SiH/Vi ratio data in Table 1A (and repeated in Table 2) and the via depth data listed in Table 2, for 40 μm thick films of the butyl acetate-silicone formulation of Examples (7A) to (7H), an SiH/Vi ratio of from 0.7 to 1.0, especially from 0.8 to 1.0, is effective for patterning through vias therein having a depth of from 90% to 100% of the thickness of the film, i.e., having little or no film material loss in the patterning step. For example, the inventive formulations having an SiH/Vi ratio of from 0.7 to 1.0, especially from 0.8 to 1.0, are effective for patterning a via in a 40 μm thick film and having at least 20 μm, alternatively at least 30 μm bottom opening (on the substrate) of the respective concentrated silicone formulation of Examples (7C) to (7H).

### Example 8: Butyl Acetate-Silicone Formulation

Mix together 100 parts of Masterbatch 1; 37±1 parts of additional Linear 1; and 16±1 parts butyl acetate. Then add 0.002 part of a platinum hydrosilylation catalyst to give the butyl acetate-silicone formulation of Ex. (8). Butyl acetate-silicone formulation of Ex. (8) is useful for forming films thereof having a thickness from 30 to 100 μm (e.g., 40 μm). The constituents and SiH/Vi ratio of this butyl acetate-silicone formulation are the same as those for formulation (7E) listed above in Tables 1A and 1B. Datum for shelf life stability of the butyl acetate-silicone formulation of Ex. 8 is reported later in Table 3. If desired, the formulation of Ex. 8 may be further processed to lower the cyclic siloxanes content thereof.

### Comparative Example (A): Xylenes-Silicone Formulation

Replicate the procedure of Example 8 except use 16±1 parts xylenes instead of the butyl acetate to give the xylenes-silicone formulation of Comparative Example (A). Datum for shelf life stability of the xylenes-silicone formulation of Comparative Example (A) is reported in Table 3.

TABLE 3
shelf life stability.

| Example | | |
|---|---|---|
| No. | Vehicle | % Change in M_{w} |
| Ex. (8) | Butyl acetate | 15.4% |
| CEx. (A) | xylenes | Gel* |

*M_{w} too high to measure.

In Table 3, shelf life stability is expressed as a percent change in weight average molecular weight (M_{W}) before and after aging a test sample of the formulation at room temperature.

As shown by the data in Table 3, the butyl acetate-silicone formulation of Ex. 8 has greater chemical stability than the xylenes-silicone formulation of CEx. (A). As can be seen, using butyl acetate instead of xylenes as the vehicle in the silicone formulations gives an increase in the chemical stability of the silicone formulation. The main source of increased chemical stability is due to the butyl acetate. These beneficial effects of butyl acetate on the silicone formulation are unpredictable and unexpected.

The below claims are incorporated by reference here, and the terms “claim” and “claims” are replaced by the term “aspect” or “aspects,” respectively. Embodiments of the invention also include these resulting numbered aspects.

1. A butyl acetate-silicone formulation comprising (A) an organopolysiloxane containing an average, per molecule, of at least two silicon-bonded alkenyl groups; (B) an organosilicon compound containing an average of at least two silicon-bonded hydrogen atoms per molecule; (C) a hydrosilylation catalyst; and a coating effective amount of (D) butyl acetate; with the proviso that the formulation lacks each of the following constituents: a thermally conductive filler; an organopolysiloxane having, on average, at least two silicon-bonded aryl groups and at least two silicon-bonded hydrogen atoms in the same molecule; a phenol; a fluoro-substituted acrylate; iron; and aluminum.

2. A concentrated silicone formulation made by removing most, but not all, butyl acetate from the butyl acetate-silicone formulation of claim 1 without curing same, the formulation consisting essentially of (A) an organopolysiloxane containing an average, per molecule, of at least two alkenyl groups; (B) an organosilicon compound containing an average, per molecule, of at least two silicon-bonded hydrogen atoms in a concentration sufficient to cure the formulation; a catalytic amount of (C) a hydrosilylation catalyst; and a residual amount of (D) butyl acetate; with the proviso that the formulation lacks each of the following constituents: a thermally conductive filler; an organopolysiloxane having, on average, at least two silicon-bonded aryl groups and at least two silicon-bonded hydrogen atoms in the same molecule; a phenol; a fluoro-substituted acrylate; iron; and aluminum.

3. The formulation of claim 1 wherein (C) the hydrosilylation catalyst is a photoactivatable hydrosilylation catalyst.

4. A method of making a concentrated silicone formulation from a butyl acetate-silicone formulation comprising (A) an organopolysiloxane containing an average, per molecule, of at least two silicon-bonded alkenyl groups; (B) an organosilicon compound containing an average of at least two silicon-bonded hydrogen atoms per molecule; (C) a hydrosilylation catalyst; and a coating effective amount of (D) butyl acetate; with the proviso that the butyl acetate-silicone formulation lacks a thermally conductive filler, the method comprising coating and/or soft baking the butyl acetate-silicone formulation so as to remove from 90 percent to less than 100 percent of the coating effective amount of (D) butyl acetate therefrom without curing same so as to give a concentrated silicone formulation consisting essentially of (A) an organopolysiloxane containing an average, per molecule, of at least two alkenyl groups; (B) an organosilicon compound containing an average, per molecule, of at least two silicon-bonded hydrogen atoms; a catalytic amount of (C) a hydrosilylation catalyst; and a residual amount of (D) butyl acetate; with the proviso that the formulation lacks a thermally conductive filler.

5. A method of making a butyl acetate free curable silicone formulation, the method comprising removing all of the (D) butyl acetate from a butyl acetate-silicone formulation according to claim 1 without curing same to give a butyl acetate-free silicone formulation consisting essentially of (A) an organopolysiloxane containing an average, per molecule, of at least two alkenyl groups; (B) an organosilicon compound containing an average, per molecule, of at least two silicon-bonded hydrogen atoms; a catalytic amount of (C) a hydrosilylation catalyst; and lacking butyl acetate; with the proviso that the formulation lacks a thermally conductive filler.

6. A method of making a cured silicone product, the method comprising removing all of the (D) butyl acetate from a butyl acetate-silicone formulation or a concentrated silicone formulation without curing same to give a butyl acetate-free curable silicone formulation and hydrosilylation curing the butyl acetate-free curable silicone formulation to give the cured silicone product; with the proviso that the product lacks a thermally conductive filler; wherein prior to the removing step the butyl acetate silicone formulation comprised (A) an organopolysiloxane containing an average, per molecule, of at least two silicon-bonded alkenyl groups; (B) an organosilicon compound containing an average of at least two silicon-bonded hydrogen atoms per molecule; (C) a hydrosilylation catalyst; and a coating effective amount of (D) butyl acetate; with the proviso that the butyl acetate-silicone formulation lacks a thermally conductive filler; and wherein prior to the removing step the concentrated silicone formulation consisted essentially of (A) an organopolysiloxane containing an average, per molecule, of at least two alkenyl groups; (B) an organosilicon compound containing an average, per molecule, of at least two silicon-bonded hydrogen atoms in a concentration sufficient to cure the formulation; a catalytic amount of (C) a hydrosilylation catalyst; and a residual amount of (D) butyl acetate; with the proviso that the concentrated silicone formulation lacks a thermally conductive filler.

7. A method of forming a temporary-bonded substrate system comprising sequentially a functional substrate, a release layer, an adhesive layer, and a carrier substrate; the method comprising steps (a) to (d): (a) applying a butyl acetate-silicone formulation according to claim 1 to a surface of the carrier substrate to form a film of the formulation on the carrier substrate; (b) soft baking the film of step (a) so as to remove butyl acetate therefrom without curing the film to give a butyl acetate-free curable film/carrier substrate article; (c) in a bond chamber under vacuum, contacting the butyl acetate-free curable film of the article of step (b) to the release layer of a functional substrate/release layer article to give a contacted substrate system comprising sequentially a functional substrate, a release layer, a butyl acetate-free curable film, and a carrier substrate; and (d) in the bond chamber under vacuum exposing the contacted substrate system to an applied force of from greater than 1,000 Newtons (N) to 10,000 N and a temperature from 125 degrees Celsius (° C.) to 300° C. so as to partially cure the butyl acetate-free curable film to give a partially cured film in the contacted substrate system; and heating the contacted substrate system with the partially cured film at ambient pressure to give a temporary-bonded substrate system comprising sequentially the functional substrate, the release layer, an adhesive layer, and the carrier substrate.

8. The method of claim 7 wherein:
step (a) further comprises exposing the film of the formulation on the carrier substrate article to ultraviolet radiation having a wavelength comprising I-line radiation so as to produce an exposed film on the carrier substrate; or
the method further comprises a step of forming the functional substrate/release layer article prior to step (c) by soft baking a film of a solvent-containing release layer composition on the functional substrate so as to remove the solvent therefrom to give the functional substrate/release layer article; or
step (a) further comprises exposing the film of the formulation on the carrier substrate article to ultraviolet radiation having a wavelength comprising I-line radiation so as to produce an exposed film on the carrier substrate and the method further comprises a step of forming the functional substrate/release layer article prior to step (c) by soft baking a film of a solvent-containing release layer composition on the functional substrate so as to remove the solvent therefrom to give the functional substrate/release layer article; or
the functional substrate is a device wafer; or
steps (c) and (d) are performed simultaneously; or
both the functional substrate is a device wafer and steps (c) and (d) are performed simultaneously.

9. The temporary-bonded substrate system made by the method of any one of claim 7.

10. A method of debonding, the method comprising subjecting the temporary-bonded substrate system of claim 9 to a debonding condition comprising applying a mechanical force so as to separate the functional substrate from the carrier substrate or vice versa to give an intact functional substrate.

11. A method of forming a permanent-bonded substrate system sequentially consisting essentially of a functional substrate/adhesive layer/carrier substrate, the method comprising steps (a) to (d): (a) applying a butyl acetate-silicone formulation according to claim 1 to a surface of the carrier substrate or the functional substrate to form an article of a film of the formulation on the carrier substrate or the functional substrate; (b) soft baking the film of the article of step (a) so as to remove butyl acetate therefrom without curing the film to give an article of a butyl acetate-free curable film on the carrier substrate or the functional substrate; (c) in a bond chamber under vacuum, contacting the butyl acetate-free curable film of step (b) to the other of the carrier substrate or functional substrate to give a contacted substrate system consisting essentially of sequentially a functional substrate, a butyl acetate-free curable film, and a carrier substrate; and (d) in the bond chamber under vacuum exposing the contacted substrate system to an applied force of from greater than 1,000 Newtons (N) to 10,000 N and a temperature from 125 degrees Celsius (° C.) to 300° C. so as to partially cure the butyl acetate-free curable film to give a partially cured film in the contacted substrate system; and heating the contacted substrate system with the partially cured film at ambient pressure to give a permanent-bonded substrate system consisting essentially of sequentially the functional substrate, an adhesive layer, and the carrier substrate.

12. An article comprising a substrate and a butyl acetate-silicone formulation according to claim 1, wherein the formulation is disposed on the substrate.

13. An optical article comprising an element for transmitting light, the element comprising the cured silicone product made by the method of claim 6, wherein the cured silicone product is an optical protective layer or a deformable membrane for use in a microelectromechanical system (MEMS).

14. An optical device with a deformable membrane, the device comprising: (a) a deformable membrane having front and rear faces and a peripheral area which is anchored in a sealed manner on a support helping to contain a constant volume of liquid in contact with the rear face of the membrane, said peripheral area is an anchoring area that is a sole area of the membrane that is anchored on the support; and a substantially central area, configured to be deformed reversibly from a rest position; and (b) an actuation device configured for displacing the liquid in the central area, stressing the membrane in at least one area situated strictly between the central area and the anchoring area, wherein the deformable membrane is the cured silicone product made by the method of claim 6.

15. A method of preparing a cured silicone layer of a semiconductor package comprising a semiconductor device wafer having an active surface comprising a plurality of surface structures including bond pads, scribe lines, and other structures; and a cured silicone layer covering the active surface of the wafer except the bond pads and scribe lines, the method comprising the steps of: (i) applying a butyl acetate-silicone formulation according to claim 1 to the active surface of the semiconductor device wafer to form a coating thereon, wherein the active surface comprises a plurality of surface structures; (ii) removing from 90 percent to less than 100 percent of the coating effective amount of (D) butyl acetate from the coating so as to give a film of a formulation consisting essentially of (A) an organopolysiloxane containing an average, per molecule, of at least two alkenyl groups; (B) an organosilicon compound containing an average, per molecule, of at least two silicon-bonded hydrogen atoms in a concentration sufficient to cure the formulation; a catalytic amount of (C) a hydrosilylation catalyst; and a residual amount of (D) butyl acetate; (iii) exposing a portion of the film to radiation having a wavelength comprising I-line radiation without exposing another portion of the film to the radiation so as to produce a partially exposed film having non-exposed regions covering at least a portion of each bond pad and exposed regions covering the remainder of the active surface; (iv) heating the partially exposed film for an amount of time such that the exposed regions are substantially insoluble in a developing solvent and the non-exposed regions are soluble in the developing solvent; (v) removing the non-exposed regions of the heated film with the developing solvent to form a patterned film; and (vi) heating the patterned film for an amount of time sufficient to form the cured silicone layer.

16. The method of claim 15, wherein:
constituents (A) and (B) are proportioned in the butyl acetate-silicone formulation in such a way so as to configure the formulation with a SiH-to-alkenyl ratio, and the SiH-to-alkenyl ratio is from 0.65 to 1.05; or
the developing solvent is butyl acetate; or
constituents (A) and (B) are proportioned in the butyl acetate-silicone formulation in such a way so as to configure the formulation with a SiH-to-alkenyl ratio, and the SiH-to-alkenyl ratio is from 0.65 to 1.05 and the developing solvent is butyl acetate.

17. A cured silicone layer formed by the method of claim 15.

18. A semiconductor package comprising a semiconductor device wafer having an active surface comprising a plurality of surface structures including bond pads, scribe lines, and other structures; and a cured silicone layer covering the active surface of the wafer except the bond pads and scribe lines, wherein the cured silicone layer is prepared by the method of any one of claim 15.

19. An electronic article comprising a dielectric layer disposed on a silicon nitride layer, the dielectric layer being made of the cured silicone product made by the method of claim 6 and, when the dielectric layer is up to 40 micrometers thick, the dielectric layer is characterized by a dielectric strength greater than 1.5×10⁶ Volts per centimeter (V/cm).
